(19) United States
(12) Patent Application Publication
(10) Pub. No.: US 2025/0234752 A1
(43) Pub. Date: Jul. 17, 2025

(54) Display Module and Display Apparatus

(71) Applicants: BEIJING BOE TECHNOLOGY DEVELOPMENT CO., LTD., Beijing (CN); BOE TECHNOLOGY GROUP CO., LTD., Chaoyang District, Beijing (CN)

(72) Inventors: Dianjie Hou, Beijing (CN); Yanli Wang, Beijing (CN); Xueguang Hao, Beijing (CN); Yong Qiao, Beijing (CN); Xinyin Wu, Beijing (CN)

(21) Appl. No.: 18/852,648

(22) PCT Filed: Feb. 23, 2024
(86) PCT No.: PCT/CN2024/078363

§ 371 Date: Sep. 30, 2024

(30) Foreign Application Priority Data
Mar. 10, 2023 (CN) 202310246746.X

(51) Int. Cl. H10K 59/80; H10K 102/00

(52) U.S. Cl. CPC H10K 59/873; H10K 59/872; H10K 2102/311

(57) ABSTRACT

A display module includes a display panel, a back film, and a first protective layer. The display panel includes a main body, a bonding portion, and a bendable portion. The bendable portion includes a first transition region, a second transition region, and a bendable region. The display panel further includes a first structure and a second structure located in the first transition region. The back film includes a first back sub-film and a second back sub-film. The first back sub-film covers the main body. The second back sub-film covers the bonding portion. The first back sub-film and the second back sub-film are disconnected at the bendable portion. The first protective layer covers the bendable portion and at least a part of the second structure. An orthographic projection of the first back sub-film on the substrate partially overlaps with an orthographic projection of the first protective layer on the substrate.

### CROSS-REFERENCE TO RELATED APPLICATIONS

This application is the United States national phase of International Patent Application No. PCT/CN2024/078363, filed Feb. 23, 2024, and claims priority to Chinese Patent Application No. 202310246746.X, filed Mar. 10, 2023, the disclosures of which are hereby incorporated by reference in their entireties.

### BACKGROUND OF THE INVENTION

### Field of the Invention

The present disclosure relates to the field of display technologies, and in particular, to a display module and a display apparatus.

### DESCRIPTION OF RELATED ART

With the rapid development of display technologies, display technologies such as liquid crystal display (LCD), organic light-emitting display (OLED), quantum dot light-emitting display (QLED) and mini/micro light-emitting display (MLED) have been widely used in people's daily lives. For example, smart phones, wearable watches, televisions, notebook computers and car displays have gradually come throughout people's lives. At present, how to reduce the bezel of the display apparatus and increase the screen-to-body ratio of the display apparatus has always been the direction of display technology research and development.

### SUMMARY OF THE INVENTION

In an aspect, a display module is provided. The display module includes a display panel, a back film and a first protective layer. The display panel has a display side and a back side opposite to each other. The display panel includes a main body, a bonding potion, and a bendable portion located between the main body and the bonding potion; the main body has a display region; the bendable portion is capable of being bent toward the back side of the main body along a bending axis extending in a first direction, so that the bonding potion is bent to the back side of the main body; the bendable portion includes a first transition region, a second transition region, and a bendable region located between the first transition region and the second transition region, and the first transition region is adjacent to the main body. The display panel includes a substrate and a plurality of inorganic layers disposed on the substrate; the display panel further includes a first structure and a second structure located in the first transition region, and the first structure is stacked on the second structure; the first structure includes at least one inorganic layer, and the second structure includes at least one inorganic layer.

The back film is located on the back side of the display panel. The back film includes a first back sub-film and a second back sub-film, the first back sub-film covers the main body, the second back sub-film covers the bonding portion, and the first back sub-film and the second back sub-film are disconnected at the bendable portion. The first protective layer is located on the display side of the display panel. The first protective layer covers the bendable portion and at least a part of the second structure; and an orthographic projection of the first back sub-film on the substrate partially overlaps with an orthographic projection of the first protective layer on the substrate.

In some embodiments, an orthographic projection of the first structure on the substrate has a first border away from the display region; an orthographic projection of the second structure on the substrate has a second border away from the display region; the orthographic projection of the first back sub-film on the substrate has a third border located in the bendable portion; and the first border, the second border, and the third border all extend in a first direction, and the second border is located between the first border and the third border.

In some embodiments, a distance between the second border and a lower boundary of the display region is less than or equal to 0.42 mm, and is greater than or equal to 0.35 mm.

In some embodiments, a distance between the second border and a lower boundary of the display region is less than or equal to 0.5 mm, and is greater than or equal to 0.45 mm.

In some embodiments, a distance between the second border and a lower boundary of the display region is less than or equal to 0.6 mm, and is greater than or equal to 0.55 mm.

In some embodiments, a distance between the second border and the third border is less than or equal to 0.2 mm.

In some embodiments, the distance between the second border and the third border is less than or equal to 0.08 mm.

In some embodiments, a base angle of the first structure away from the display region is a first angle, and the first angle is in a range of 20° to 70°; and/or a base angle of the second structure away from the display region is a second angle, and the second angle is in a range of 10° to 30°.

In some embodiments, the first angle is in a range of 23° to 60°; and/or the second angle is in a range of 12° to 26°.

In some embodiments, the first angle is in a range of 25° to 50°; and/or the second angle is in a range of 14° to 22°.

In some embodiments, a base angle of the second structure away from the display region is a second angle A₂, and a distance between the first border and the second border is a sixth distance D6, where 0.08≤(sinA₂)²×\sqrt{D6}≤0.3.

In some embodiments, the base angle of the second structure away from the display region is the second angle A₂, and the distance between the first border and the second border is the sixth distance D6, where 0.09≤(sinA₂)²×\sqrt{D6}≤0.28.

In some embodiments, the plurality of inorganic layers include a barrier layer, a first buffer layer, a first gate insulating layer, a first interlayer insulating layer, a second gate insulating layer, a third gate insulating layer, and a second interlayer insulating layer; the first structure includes the first gate insulating layer, the first interlayer insulating layer, the second gate insulating layer, the third gate insulating layer and the second interlayer insulating layer that are stacked in sequence; and the second structure includes the barrier layer and the first buffer layer that are stacked.

In some embodiments, the display module includes an anti-reflection layer, a second adhesive layer, and a cover plate; the anti-reflection layer is disposed on the display side of the main body of the display panel; the second adhesive layer is disposed on a side of the anti-reflection layer away from the main body; the cover plate is disposed on a side of the second adhesive layer away from the main body; and the first protective layer is in contact with the anti-reflection layer.

In another aspect, a display apparatus is provided. The display apparatus includes the display module as described in any of the above embodiments and a housing. The housing includes a bottom plate and a frame surrounding the bottom plate. The bottom plate is disposed on the back side of the display panel of the display module, and the frame surrounds a periphery of the display panel.

In some embodiments, a part of the frame located on a side of the bendable portion of the display panel away from the main body of the display panel is a first frame; a minimum distance between a boundary of the display region and a boundary of an orthographic projection of the first frame on a reference plane is a first distance, the reference plane being a plane where a display surface of the main body of the display panel is located; a minimum distance between a boundary of an orthographic projection of the bendable portion on the reference plane and the boundary of the orthographic projection of the first frame on the reference plane is a second distance; and a ratio of the first distance to the second distance is greater than or equal to 5 and less than or equal to 10.

In some embodiments, a part of the frame located on a side of the bendable portion of the display panel away from the main body is a first frame; an inner side of the first frame is recessed in a direction away from the bendable portion to form an avoidance structure; in a second direction, the avoidance structure is at least opposite to a part of the bendable portion that is farthest from the main body, the second direction is substantially parallel to a reference plane and points from the main body to the bendable portion, and the reference plane is a plane where a display surface of the main body of the display panel is located; a minimum distance between the bendable portion and the avoidance structure is greater than or equal to a first preset value, and the first preset value is a process limit value at which the bendable portion does not interfere with the first frame.

In some embodiments, a part of the frame located on a side of the bendable portion of the display panel away from the main body is a first frame. The display apparatus further includes a first fixed portion and a second fixed portion. The first fixed portion covers a side of the bendable portion away from the first frame and extends to the main body and the bonding portion. The second fixed portion covers at least a part of a side of the bendable portion close to the first frame and extends to the main body and the bonding portion.

In some embodiments, the second fixed portion covers the side of the bendable portion close to the first frame, and the second fixed portion and the first frame enclose at least one first cavity; and/or the second fixed portion covers the part of the side of the bendable portion close to the first frame, and the second fixed portion, the bendable portion and the first frame enclose at least one second cavity.

In some embodiments, the second fixed portion is provided with a first limiting structure, and the first limiting structure is located on a side of the second fixed portion close to the first frame; the first frame is provided with a second limiting structure, and the second limiting structure is located on a side of the first frame close to the second fixed portion. The first limiting structure is connected to the second limiting structure to limit a relative motion of the second fixed portion with respect to the first frame.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a sectional view taken along the section line C-C′ in FIG. 1;

FIG. 3 is a top view of a display panel in a display apparatus, in accordance with some embodiments;

FIG. 4 is a top view of a display panel in a display apparatus, in accordance with some other embodiments;

FIG. 5 is a top view of a display panel in a display apparatus, in accordance with yet some other embodiments;

FIG. 6A is a top view of a display panel in a display apparatus, in accordance with yet some other embodiments;

FIG. 6B is a top view of a display panel in a display apparatus, in accordance with yet some other embodiments;

FIG. 6C is a top view of a display panel in a display apparatus, in accordance with yet some other embodiments;

FIG. 7A is a sectional view taken along the section line D-D′ in FIG. 1;

FIG. 7B is another sectional view taken along the section line D-D′ in FIG. 1;

FIG. 7C is yet another sectional view taken along the section line D-D′ in FIG. 1;

FIG. 8A is a structural diagram of a substrate, in accordance with some embodiments;

FIG. 8B is a structural diagram of another substrate, in accordance with some embodiments;

FIG. 9A is a structural diagram of a display panel in an unfolded state, in accordance with some embodiments;

FIG. 9B is a sectional view taken along the section line F-F′ in FIG. 9A;

FIG. 10A is a structural diagram of a display module, in accordance with some embodiments;

FIG. 10B is a structural diagram of another display module, in accordance with some embodiments;

FIG. 10C is a structural diagram of yet another display module, in accordance with some embodiments;

FIG. 11 is a structural diagram of a display apparatus before a display panel is bent, in accordance with some embodiments.

FIG. 12 is a structural diagram of a display apparatus before a display panel is bent, in accordance with some other embodiments;

FIG. 13A is a partial enlarged view of a bendable portion of a display panel in FIG. 10A;

FIG. 13B is a partial enlarged view of a bendable portion of a display panel in FIG. 10B;

FIG. 13C is a partial enlarged view of a bendable portion of a display panel in FIG. 10C;

FIG. 14A is a structural diagram of a display module, in accordance with some embodiments;

FIG. 14B is a structural diagram of another display module, in accordance with some embodiments;

FIG. 14C is a structural diagram of yet another display module, in accordance with some embodiments.

FIG. 15 is a sectional view taken along the section line E-E′ in FIG. 1;

FIG. 16 is another sectional view taken along the section line E-E′ in FIG. 1;

FIG. 17 is yet another sectional view taken along the section line E-E′ in FIG. 1;

FIG. 18 is yet another sectional view taken along the section line E-E′ in FIG. 1;

FIG. 19 is yet another sectional view taken along the section line E-E′ in FIG. 1;

FIG. 20 is yet another sectional view taken along the section line E-E′ in FIG. 1;

FIG. 21 is yet another sectional view taken along the section line E-E′ in FIG. 1;

FIG. 22 is yet another sectional view taken along the section line E-E′ in FIG. 1;

FIG. 23 is yet another sectional view taken along the section line E-E′ in FIG. 1;

FIG. 24 is yet another sectional view taken along the section line E-E′ in FIG. 1;

FIG. 25 is yet another sectional view taken along the section line E-E′ in FIG. 1;

FIG. 26 is yet another sectional view taken along the section line E-E′ in FIG. 1;

FIG. 27 is yet another sectional view taken along the section line E-E′ in FIG. 1;

FIG. 28 is yet another sectional view taken along the section line E-E′ in FIG. 1;

FIG. 29 is yet another sectional view taken along the section line E-E′ in FIG. 1;

FIG. 30 is yet another sectional view taken along the section line E-E′ in FIG. 1; and

FIG. 31 is yet another sectional view taken along the section line E-E′ in FIG. 1.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

The terms such as “first” and “second” are used herein to describe various elements, but the elements should not be limited by these terms. These terms are only used to distinguish one component from other components. For example, an element referred to as a first element in an embodiment could be referred to as a second element in another embodiment without departing from the scope of the appended claims. Unless mentioned otherwise, terms in the singular form may include plural forms.

In the description of some embodiments, the term “connected” and derivatives thereof may be used. The term “connected” shall be understood in a broad sense. For example, the term “connected” may represent a fixed connection, or a detachable connection, or a one-piece connection; alternatively, the term “connected” may represent a direct connection, or an indirect connection through an intermediate medium.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

In addition, the phrase “based on” used is meant to be open and inclusive, since a process, step, calculation or other action that is “based on” one or more of the stated conditions or values may, in practice, be based on additional conditions or values exceeding those stated.

The term such as “about”, “substantially” or “approximately” as used herein include a stated value and means within an acceptable range of deviation of a particular value determined by a person of ordinary skill in the art, considering measurement in question and errors associated with measurement of a particular quantity (i.e., limitations of a measurement system). For example, “about” may mean within one or more standard deviations, or within ±30%, ±20%, ±10%, ±5% of the stated value.

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

In the specification, unless otherwise defined, all terms (including technical terms and scientific terms) used herein have the same meaning as commonly understood by a person of ordinary skill in the art. It will be further understood that unless explicitly defined herein, terms (such as those defined in commonly used dictionaries) should be interpreted as having a meaning that is consistent with their meaning in the context of the relevant art, and should not be interpreted as an ideal or overly formal meaning.

In the specification, when a component (or region, layer, portion) is described as “covering” another component, the component may directly cover the another component. Alternatively, there may be a third component sandwiched between the component and the another component.

In the present disclosure, terms such as “lower,” “below,” “above,” and “upper,” are used to explain the relational association of components shown in the drawings. The terms may be relative concepts and described based on directions indicated in the drawings, but are not limited thereto.

The term “overlap” or “overlapping” means that a first object may be above or below or to a side of a second object, and vice versa. In addition, the term “overlapping” may include layering, stacking, facing, extending over, covering or partially covering, or any other suitable term that would be appreciated and understood by a person of ordinary skill in the art.

When an element is described as “not overlapping” or “will not overlap” another element, it may include the elements being spaced apart, offset, or separated from each other, or any other suitable terminology that would be appreciated and understood by one of ordinary skill in the art.

The term “opposite to” means that a first element may be directly or indirectly opposite to a second element. In the case where a third element is interposed between the first element and the second element, the first element and the second element may be understood as being indirectly opposite to each other although still opposite to each other.

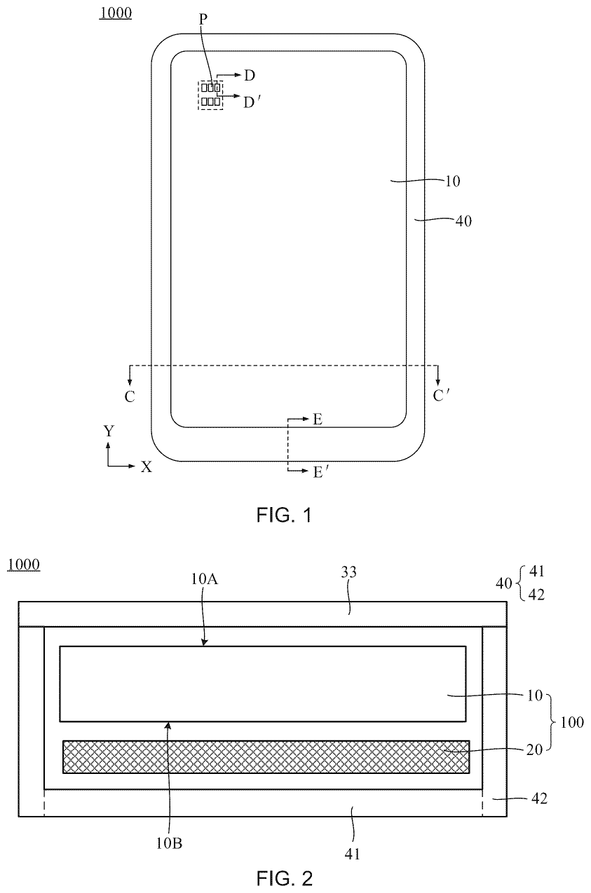

As shown in FIG. 1, some embodiments of the present disclosure provide a display apparatus 1000. The display apparatus 1000 may be any apparatus that can display an image whether in motion (e.g., a video) or stationary (e.g., a still image), and whether textual or graphical.

For example, referring to FIG. 1, the display apparatus 1000 may be any product or component having a display function, such as a television, a notebook computer, a tablet computer, a mobile phone, a personal digital assistant (PDA), a navigator, a vehicle-mounted display, a flight display, a wearable device, or a virtual reality (VR) device.

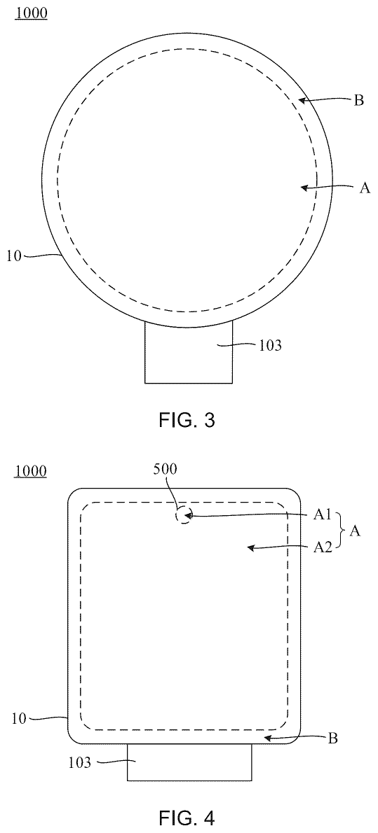

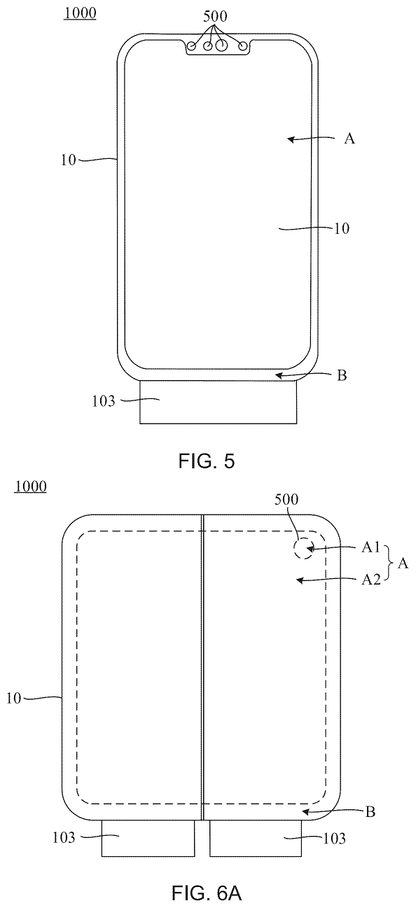

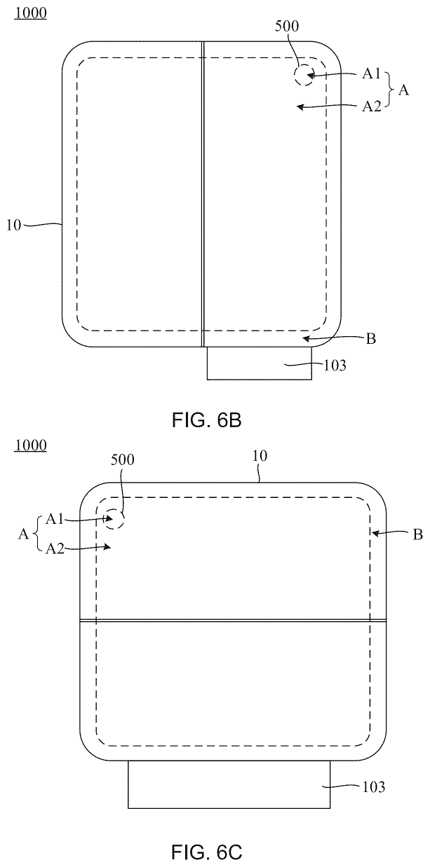

For example, referring to FIGS. 3 and 4, the display apparatus 1000 may be a wearable device. The wearable device may be a round watch as shown in FIG. 3 or a square watch as shown in FIG. 4. As another example, the display apparatus 1000 may be a mobile phone. The mobile phone may be a bar mobile phone as shown in FIG. 5, or a foldable mobile phone as shown in FIGS. 6A to 6C.

The display apparatus 1000 may be one of a flat display apparatus, a curved display apparatus, a foldable display apparatus, or a rollable display apparatus. For example, the display apparatus 1000 may be a display apparatus having curved surfaces on two sides.

Some embodiments of the present disclosure will be illustrated by taking an example in which the display apparatus 1000 is a curved display apparatus, but the implementations of the present disclosure are not limited thereto. Any other display apparatus 1000 may also be considered as long as the same technical concept is applied.

In some embodiments, referring to FIG. 2, the display apparatus 1000 includes a display module 100; the display module 100 includes a display panel 10; and the display panel 10 has a display side 10A and a back side 10B that are opposite to each other.

It will be noted that the display side 10A refers to a side of the display panel 10 for displaying images (an upper side of the display panel 10 in FIG. 2), and the back side 10B refers to another side opposite to the display side 10A (a lower side of the display panel 10 in FIG. 2).

As shown in FIGS. 3 to 6C, the display panel 10 has a display region A and a peripheral region B disposed on at least one side of the display region A. FIG. 5 illustrates an example in which the peripheral region B surrounds the display region A.

It will be noted that the display region A is a region for displaying images, and is configured to be provided therein with a plurality of sub-pixels P (see FIG. 1). The peripheral region B is a region where no image is displayed therein. The peripheral region B is configured to be provided therein with display driver circuits, such as a gate driver circuit and a source driver circuit.

The display panel 10 may be an organic light-emitting diode display panel, a quantum dot light-emitting diode display panel, a micro/mini light-emitting diode display panel, a liquid crystal display panel, a plasma display panel, a field emission display panel, an electrowetting display panel or an electrophoretic display panel, which will not be specifically limited in the embodiments of the present disclosure.

Some embodiments of the present disclosure will be illustrated by taking an example in which the display panel 10 is an organic light-emitting diode display panel, but the implementations of the present disclosure are not limited thereto. Any other display panel may also be considered as long as the same technical concept is applied.

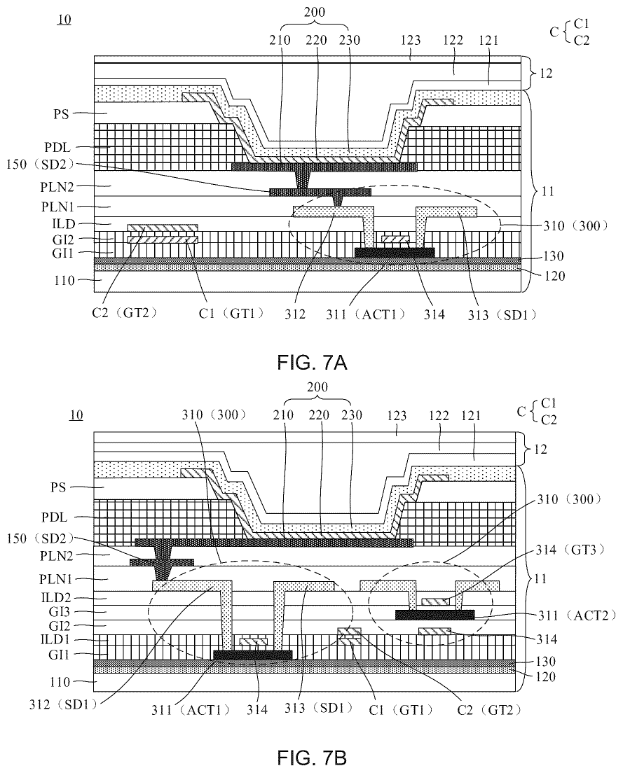

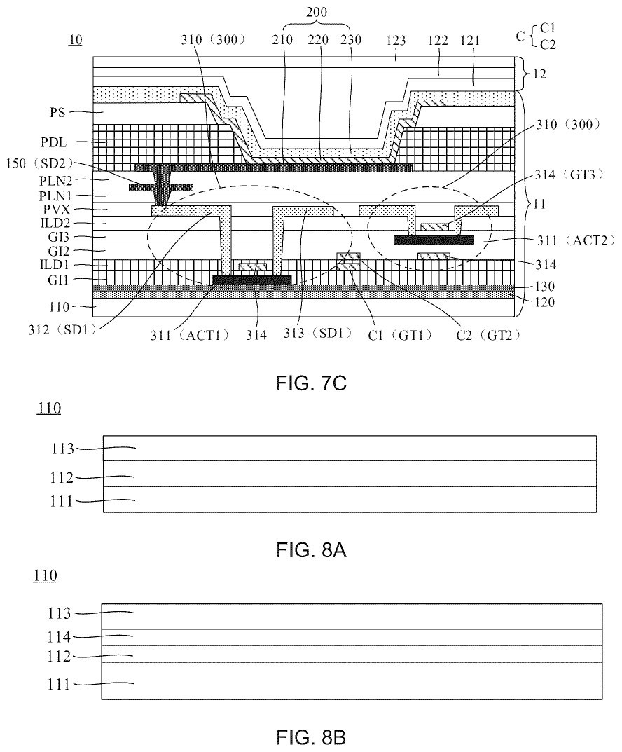

In some embodiments, as shown in FIG. 7A, the display panel 10 includes a display substrate 11 and an encapsulation layer 12 for encapsulating the display substrate 11.

The display substrate 11 has a light-emitting side and a non-light-emitting side that are opposite to each other. The encapsulation layer 12 is disposed on the light-emitting side of the display substrate 11 to prevent shortening of the service life of the display panel 10 caused by water vapor and oxygen in the external environment entering the display panel 10.

The encapsulation layer 12 may be an encapsulation film or an encapsulation substrate.

For example, as shown in FIG. 7A, the encapsulation layer 12 is an encapsulation film, and includes a first inorganic encapsulation layer 121, an organic encapsulation layer 122 and a second inorganic encapsulation layer 123 that are stacked in sequence.

Referring to FIGS. 1 and 7B, the display substrate 11 includes a substrate 110 and a plurality of sub-pixels P disposed on the substrate 110. Each sub-pixel P includes a light-emitting device 200 and a pixel circuit 300 disposed on the substrate 110.

Referring to FIG. 1, the plurality of sub-pixels P may be, for example, arranged in a plurality of rows and a plurality of columns; a row of sub-pixels P includes multiple sub-pixels P arranged in a first direction X; and a column of sub-pixels P includes multiple sub-pixels P arranged in a second direction Y. The first direction X is substantially perpendicular to the second direction Y.

It will be noted that the first direction X may be, for example, a row direction in which the plurality of sub-pixels P are arranged, and the second direction Y may be, for example, a column direction in which the plurality of sub-pixels P are arranged.

Referring to FIG. 1, the plurality of sub-pixels P may include first sub-pixels emitting light of a first color, second sub-pixels emitting light of a second color, and third sub-pixels emitting light of a third color. The first color, the second color, and the third color are three primary colors. For example, the first color is red, the second color is blue, and the third color is green, which is not specifically limited in the embodiments of the present disclosure.

As shown in FIG. 7A, the pixel circuit 300 includes a plurality of transistors 310 and a storage capacitor C. The storage capacitor Cst includes a first capacitor electrode C1 and a second capacitor electrode C2. The transistor 310 includes an active layer 311, a source 312, a drain 313 and a gate 314. The source 312 and the drain 313 are in contact with the active layer 311.

It will be noted that the transistor 310 may be a low-temperature polysilicon thin film transistor, that is, the active layer 311 of the transistor 310 is made of low-temperature polysilicon. The transistor 310 may also be an oxide transistor, that is, the active layer 311 of the transistor 310 is made of metal oxide, such as indium gallium zinc oxide or indium gallium tin oxide. In addition, the source 312 and the drain 313 may be interchanged, that is, the reference character “312” in FIG. 7A represents the drain, and the reference character “313” in FIG. 7A represents the source.

As shown in FIG. 7A, the light-emitting device 200 includes a first electrode 210, a light-emitting functional layer 220 and a second electrode 230. The first electrode 210 is electrically connected to a source 312 or a drain 313 of a transistor 310 among the plurality of transistors 310. FIG. 7A illustrates an electrical connection between the first electrode 210 and the source 312 of the transistor 310.

It will be noted that the first electrode 210 is an anode of the light-emitting device 200, and the second electrode 230 is a cathode of the light-emitting device 200. Alternatively, the first electrode 210 may be the cathode of the light-emitting device 200, and the second electrode 230 may be the anode of the light-emitting device 200. FIG. 7A illustrates an example in which the first electrode 210 is the anode of the light-emitting device 200 and the second electrode 230 is the cathode of the light-emitting device 200.

In some embodiments, the light-emitting functional layer 220 only includes a light-emitting layer. In some other embodiments, in addition to the light-emitting layer, the light-emitting functional layer 220 further includes at least one of an electron transport layer (ETL), an electron injection layer (EIL), a hole transport layer (HTL) or a hole injection layer (HIL).

It will be understood that the substrate 110 may be of a single-layer or multi-layer structure.

In some examples, as shown in FIG. 7A, the substrate 110 may be a single-layer glass substrate.

In other examples, as shown in FIGS. 7A and 8A, the substrate 110 includes a first organic base 111, a first inorganic base 112, and a second organic base 113 that are sequentially stacked in a direction perpendicular to the substrate 110 and pointing from the substrate 110 to the encapsulation layer 12.

The materials of the first organic base 111 and the second organic base 113 may each include at least one of polyimide (PI), polyethylene terephthalate (PET), or a carbon fiber composite material. When the materials of the first organic base 111 and the second organic base 113 each include polyimide, polyimide may be yellow polyimide or transparent polyimide. Here, transparent polyimide means that the light transmittance of polyimide is greater than or equal to 90%.

The material of the first inorganic base 112 may include at least one of silicon oxide, silicon nitride, a glass fiber composite material or a ceramic material.

In some other examples, as shown in FIG. 8B, in addition to the first organic base 111, the first inorganic base 112, and the second organic base 113, the substrate 110 further includes a support layer 114 disposed between the first inorganic base 112 and the second organic base 113 to improve the strength of the substrate 110.

The material of the support layer 114 includes metal or a semiconductor material. For example, the material of the support layer 114 includes at least one of copper, steel, or a silicon compound (e.g., polysilicon).

In some embodiments, as shown in FIG. 7A, the pixel circuit 300 includes only low-temperature polysilicon thin film transistors. In this case, the display substrate 11 includes a low-temperature polycrystalline silicon semiconductor ACT1, a first gate insulating layer GI1, a first gate pattern GT1, a second gate insulating layer GI2, a second gate pattern GT2, an interlayer insulating layer ILD, a first source-drain conductive layer SD1, a first planarization layer PLN1, a second source-drain conductive layer SD2 and a second planarization layer PLN2 that are sequentially stacked in the direction perpendicular to the substrate 110 and pointing from the substrate 110 to the encapsulation layer 12.

As shown in FIG. 7A, the low-temperature polysilicon semiconductor ACT1 may include active layers 311 of the transistors 310 (the low-temperature polysilicon thin film transistors). The first gate pattern GT1 may include gates 314 of the transistors 310 (the low temperature polysilicon thin film transistors).

As shown in FIG. 7A, the first source-drain conductive layer SD1 may include sources 312 and drains 313 of the transistors 310. The second source-drain conductive layer SD2 may include transfer electrodes 150, and a transfer electrode 150 is in electrical contact with the first electrode 210 and the source 312, so that the first electrode 210 is electrically connected to the source 312.

On this basis, the first gate pattern GT1 may further include first capacitor electrodes C1, and the second gate pattern GT2 may include second capacitor electrodes C2. An orthographic projection of the first capacitor electrode C1 on the substrate 110 at least partially overlaps with an orthographic projection of the second capacitor electrode C2 on the substrate 110, so as to form the storage capacitor C in the pixel circuit 300.

In some other embodiments, the low-temperature polysilicon thin film transistors have advantages such as high mobility and fast charging, and the oxide thin film transistors have advantages such as low leakage current; the low-temperature polysilicon thin film transistors and the oxide thin film transistors are integrated on a display panel 10, that is, the pixel circuit 300 includes low-temperature polysilicon thin film transistors and oxide transistors; therefore, due to their advantages, it may be possible to realize low-frequency driving, reduce power consumption, and improve display quality.

In this case, as shown in FIG. 7B, the display substrate 11 includes a low-temperature polycrystalline silicon semiconductor ACT1, a first gate insulating layer GI1, a first gate pattern GT1, a first interlayer insulating layer ILD1, a second gate pattern GT2, a second gate insulating layer GI2, an oxide semiconductor ACT2, a third gate insulating layer GI3, a third gate conductive layer GT3, a second interlayer insulating layer ILD2, a first source-drain conductive layer SD1, a first planarization layer PLN1, a second source-drain conductive layer SD2 and a second planarization layer PLN2 that are sequentially stacked in the direction perpendicular to the substrate 110 and pointing from the substrate 110 to the encapsulation layer 12.

As shown in FIG. 7B, the low-temperature polysilicon semiconductor ACT1 may include active layers 311 of transistors 310 (the low-temperature polysilicon thin film transistors). The first gate pattern GT1 may include gates 314 of the transistors 310 (the low temperature polysilicon thin film transistors). The oxide semiconductor ACT2 may include active layers 311 of transistors 310 (the oxide transistors).

As shown in FIG. 7B, the second gate pattern GT2 may include gates 314 of the transistors 310 (the oxide transistors) serving as bottom gates of the transistors 310 (the oxide transistors). The third gate pattern GT3 may include gates 314 of the transistors 310 (the oxide transistors) serving as top gates of the transistors 310 (the oxide transistors). Therefore, a double-gate structure is formed, which reduces the leakage current of the transistors 310 (the oxide transistors).

As shown in FIG. 7B, the first source-drain conductive layer SD1 may include sources 312 and drains 313 of the transistors 310 (the low-temperature polysilicon thin film transistors and the oxide transistors). The second source-drain conductive layer SD2 may include transfer electrodes 150, and a transfer electrode 150 is in electrical contact with the first electrode 210 and the source 312, so that the first electrode 210 is electrically connected to the source 312.

On this basis, the first gate pattern GT1 may further include first capacitor electrodes C1, and the second gate pattern GT2 may include second capacitor electrodes C2. An orthographic projection of the first capacitor electrode C1 on the substrate 110 at least partially overlaps with an orthographic projection of the second capacitor electrode C2 on the substrate 110, so as to form the storage capacitor C in the pixel circuit 300.

Some embodiments of the present disclosure will be schematically illustrated by taking an example in which the pixel circuit 300 includes low-temperature polycrystalline silicon thin film transistors and oxide transistors. That is, the display substrate 11 includes the low-temperature polycrystalline silicon semiconductor ACT1 and the third gate conductive layer GT3. However, the implementations of the present disclosure are not limited thereto. Any other display substrate may also be considered as long as the same technical concept is applied.

In some embodiments, as shown in FIG. 7B, the display substrate 11 further includes a pixel defining layer PDL, the pixel defining layer PDL includes a plurality of opening regions, and a light-emitting device 200 is arranged in an opening region.

In some embodiments, referring to FIG. 7B, the display substrate 11 further includes spacers 17, and the spacers 17 are disposed between the pixel defining layer PDL and the light-emitting functional layer 220.

In some embodiments, as shown in FIG. 7C, the display substrate 11 further includes a passivation layer PVX, the passivation layer PVX is disposed on a side of the first source-drain conductive layer SD1 away from the substrate 110, and the first planarization layer PLN1 is located on a side of the passivation layer PVX away from the substrate 110.

In some embodiments, as shown in FIGS. 7A, 7B and 7C, the display substrate 11 may further include a barrier layer 120 and a first buffer layer 130, the barrier layer 120 and the first buffer layer 130 are disposed between the substrate 110 and the transistors 310, and the first buffer layer 130 is located on a side of the barrier layer 120 away from the substrate 110.

In some embodiments, referring to FIGS. 4 to 6C, the display apparatus 1000 further includes a functional device 500. The functional device 500 may be a camera, an infrared sensor, a proximity sensor, an eyeball tracking module, a face recognition module, etc. For example, the functional device 500 is a camera.

In some examples, referring to FIGS. 4 and 6A, the functional device 500 may be integrated below the display panel 10 to increase the screen-to-body ratio and reduce the peripheral region B, thereby reducing the bezel of the display apparatus 1000.

In the case where the functional device 500 is integrated below the display panel 10, the display region A further has a functional device arrangement region A1 and a main display region A2 at least partially surrounding the functional device arrangement region A1. The functional device 500 is located in the functional device arrangement region A1. For example, as shown in FIGS. 4 and 6A, the main display region A2 surrounds the functional device arrangement region A1.

It will be noted that, as shown in FIG. 4, the functional device arrangement region A1 may be located in the middle of the upper side of the display region A; alternatively, as shown in FIG. 6A, the functional device arrangement region A1 may be located at the upper left or right corner of the display region A. FIGS. 6A and 6B illustrate examples in which the functional device arrangement region A1 is located at the upper right corner of the display region A. FIG. 6C illustrates an example in which the functional device arrangement region A1 is located at the upper left corner of the display region A.

In some other examples, referring to FIG. 5, the display panel 10 is provided with an opening penetrating the display panel 10, and the functional device 500 may be disposed in the opening to avoid interference between the functional device 500 and the display panel 10 during the assembly process.

It will be noted that the opening may be located in the middle of the upper side of the display region A; or, the opening may be located at the upper left or right corner of the display region A. The opening located at the upper left corner of the display region A is taken as an example for illustration. FIG. 5 illustrates an example in which the opening may be located in the middle of the upper side of the display region A.

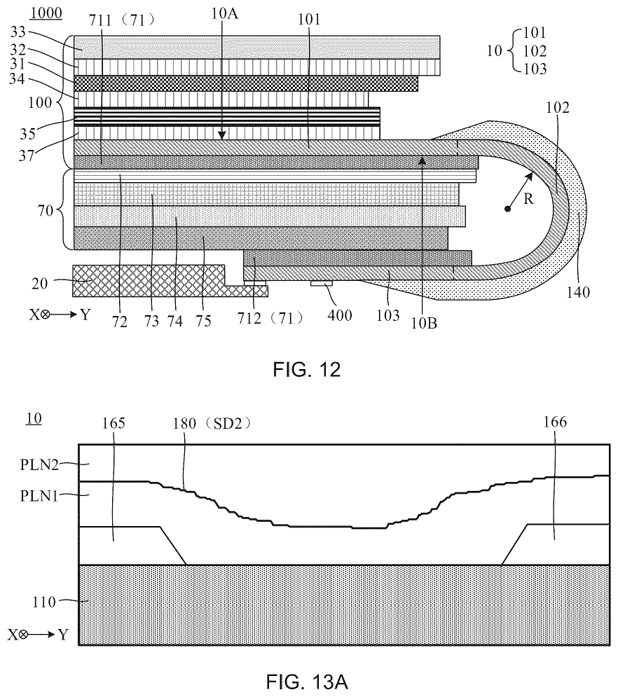

In some embodiments, as shown in FIGS. 11 and 12, the display module 100 further includes a circuit board 20, and the circuit board 20 may be bonded to the display panel 10 at an end of the display panel 10. In addition, the circuit board 20 may be bent along with the display panel 10 to the back side of the display panel 10, so as to reduce the bezel of the display apparatus 1000.

For example, referring to FIG. 11, the display panel 10 includes a main body 101, a bendable portion 102 and a bonding portion 103 that are connected in sequence. The bendable portion 102 is located on a side of the main body 101, and the bonding portion 103 is located on a side of the bendable portion 102 away from the main body 101. That is, the bendable portion 102 is located between the main body 101 and the bonding portion 103.

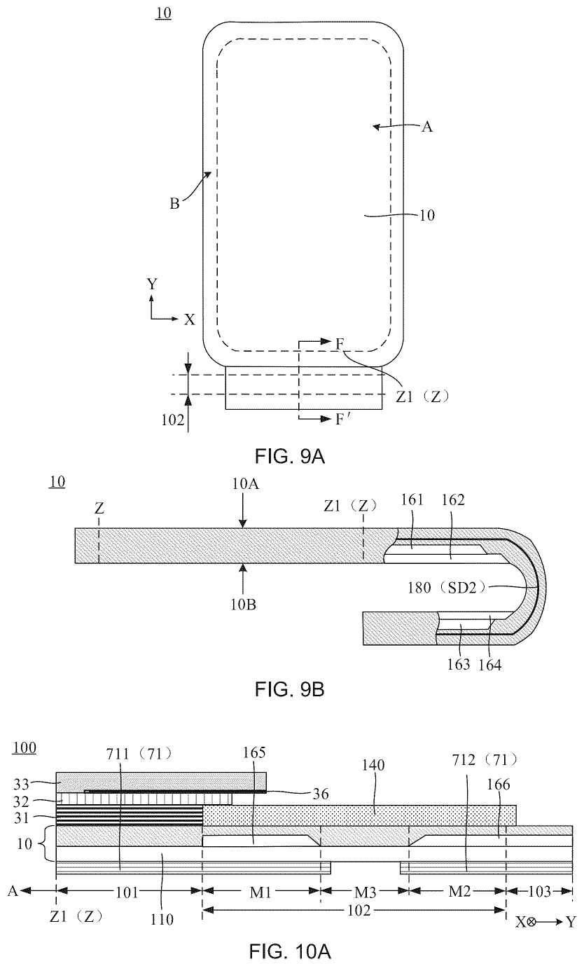

It will be noted that the display panel 10 has two states, which are an unfolded state and a bent state. The unfolded state is shown in FIGS. 9A and 11, and the bent state is shown in FIGS. 9B and 12. The positional relationship of all parts of the display panel 10 will be described below taking the unfolded state as an example, but the embodiments of the present disclosure are not limited thereto. In addition, in order to more clearly describe the content of the embodiments of the present disclosure, a part of a boundary Z of the display region A close to the bendable portion 102 is referred to as a lower boundary Z1.

In the case where the display region A is substantially in a shape of a rectangle, a part of the boundary of the display region A refers to a contour line of outer edges (edges away from a geometric center of the display region A) of anodes of an outermost column of sub-pixels P or an outermost row of sub-pixels P. For example, the lower boundary Z1 of the display region A refers to a contour line of outer edges of anodes of a lowermost row of sub-pixels P.

In the case where the display region A is substantially in a shape of a circle, the boundary of the display region A refers to a contour line of outer edges (edges away from a geometric center of the display region A) of anodes of sub-pixels P in an outermost circle. For example, the lower boundary Z1 of the display region A refers to a lower semicircle of a circle formed by the contour line of the outer edges of the anodes of the sub-pixels P in the outermost circle. In some cases, “substantially in a shape of a circle” herein includes a plurality of broken line segments that are connected end-to-end to have an approximately circular shape.

As shown in FIG. 11, the main body 101 may be a portion of the display panel 10 for displaying images. That is to say, the display region A (see FIGS. 3 to 6B) is located in the main body 101, that is, the main body 101 has the display region A (see FIGS. 3 to 6B).

Referring to FIGS. 5 and 11, the main body 101 may further include a part of the peripheral region B. For example, as shown in FIGS. 3 to 6B, an orthographic projection of the main body 101 on a reference plane is substantially in a shape of any one of a circle, an ellipse, a rectangle, etc., which is not specifically limited in the embodiments of the present disclosure.

It will be noted that the reference plane is a plane where a display surface of the main body 101 of the display panel 10 is located.

Herein, “substantially in a shape of a circle or an ellipse” means in a shape of a circle or ellipse as a whole, but is not limited to a shape of a standard circle or ellipse. That is, the “shape of a circle or ellipse” here includes not only a shape of a standard circle or ellipse but also a shape similar to a circle or ellipse.

Herein, “substantially in a shape of a rectangle” means in a shape of a rectangle as a whole, but is not limited to a shape of a standard rectangle. That is, “rectangle” here includes not only a shape of a standard rectangle but also a shape similar to a rectangle. For example, long and short sides of the rectangle are curved at each intersecting position (i.e., corners), that is, the corners are smooth, and the shape is a rounded rectangle. The following description will be introduced by taking an example in which the orthographic projection, on the reference plane, of the main body 101 shown in FIG. 5 is substantially in a shape of a rounded rectangle.

As shown in FIGS. 3 to 6B, 11 and 12, the bonding portion 103 may be a portion of the display panel 10 for being bonded to the circuit board 20.

In the case where the display apparatus 1000 is a foldable mobile phone, in some examples, as shown in FIGS. 6A and 11, the display panel 10 includes two bonding portions 103 spaced apart, and the two bonding portions 103 are located on the side of the bendable portion 102 away from the main body 101. In some other examples, as shown in FIGS. 6B, 6C and 11, the display panel 10 includes one bonding portion 103, and the bonding portion 103 is located on the side of the bendable portion 102 away from the main body 101 and is connected to the main body 101 located in a non-foldable region of the display panel 10 in the foldable mobile phone.

Referring to FIG. 11, the display module 100 may further include, for example, a driver chip 400. The driver chip 400 is configured to provide the display panel 10 with data signals required for displaying images.

As shown in FIGS. 11 and 12, the driver chip 400 may be disposed on the bonding portion 103. In this way, the driver chip 400 may provide the data signals required for displaying images for the main body 101 through the bonding portion 103 and the bendable portion 102, so as to control the display panel 10 to display images.

Here, the driver chip 400 includes at least one of microchips such as a source driver chip, a touch chip, a timing controller, and a gamma circuit, which will not be specifically limited in the embodiments of the present disclosure.

For example, the driver chip 400 is a source driver chip, and the driver chip 400 is disposed on the bonding portion 103. Compared with a case where the driver chip 400 is disposed in the peripheral region B included in the main body 101, it may be possible to reduce the width of the peripheral region B included in the main body 101 and increase the screen-to-body ratio.

As shown in FIGS. 1 and 12, through a bending process, the bendable portion 102 may be bent, along a bending axis extending in the first direction X, toward the back side 10B of the main body 101 of the display panel 10, so that the bonding portion 103 is bent to the back side 10B of the main body 101 of the display panel 10, thereby reducing the bezel of the display apparatus 1000 (see FIG. 1).

It will be noted that a bending radius R of the bendable portion 102 may be in a range of 0.1 mm to 0.5 mm. For example, the bending radius R of the bendable portion 102 may be any one of 0.1 mm, 0.2 mm, 0.3 mm, 0.35 mm, 0.4 mm and 0.5 mm. The bending radius R refers to a radius from a center of a standard circle formed by a bending arc to an inner side of the bendable portion 102.

It will be understood that the smaller the bending radius R of the bendable portion 102 is, the narrower the bezel of the display apparatus 1000 corresponding to the bendable portion 102 (the lower bezel in FIG. 1) can be designed, thereby facilitating the narrow bezel design of the display apparatus 1000. For example, the bending radius R of the bendable portion 102 may be in a range of 0.1 mm to 0.2 mm. For example, the bending radius R of the bendable portion 102 may be any one of 0.12 mm, 0.15 mm and 0.18 mm. Therefore, the bezel of the display apparatus 1000 corresponding to the bendable portion 102 (the lower bezel in FIG. 1) may be made narrower.

It will be understood that the bendable portion 102 does not need to display images and the bendable portion 102 requires a certain degree of flexibility. Based on this, the bendable portion 102 may omit some film layers compared to the main body 101 or the bonding portion 103, thereby reducing the bending stress of the bendable portion 102, improving the flexibility of the bendable portion 102, and reducing the risk of cracks or breakage of the bendable portion 102.

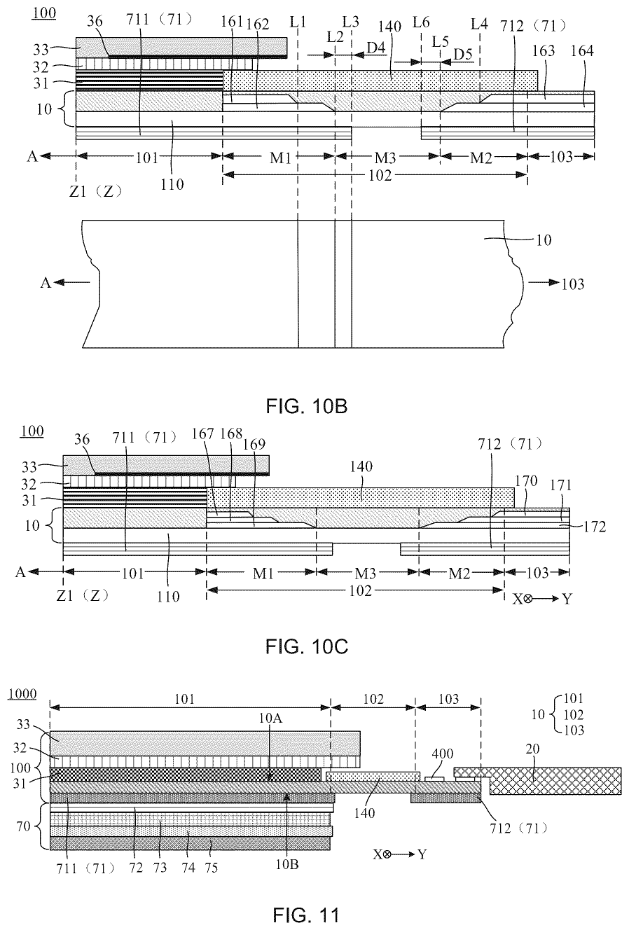

In some embodiments, referring to FIGS. 10A to 12, the bendable portion 102 includes a first transition region M1, a second transition region M2, and a bendable region M3 located between the first transition region M1 and the second transition region M2, and the first transition region M1 is adjacent to the main body 101.

As shown in FIGS. 10A to 12, the first transition region M1 and the second transition region M2 are regions where unbent extension sections of the bendable portion 102 are located; the bendable region M3 is a region where a bendable section of the bendable portion 102 is located; a part of the bendable portion 102 located in the first transition region M1 is connected to the main body 101; and a part of the bendable portion 102 located in the second transition region M2 is connected to the bonding portion 103.

In some examples, as shown in FIG. 10A, the display panel 10 includes a fifth structure 165 disposed on the substrate 110, and the fifth structure 165 is located in the first transition region M1. The display panel 10 includes a plurality of inorganic layers disposed on the substrate 110, and the fifth structure 165 includes at least one inorganic layer.

For example, as shown in FIG. 7A, when the pixel circuit 300 includes only the low-temperature polysilicon thin film transistors, the plurality of inorganic layers may include the barrier layer 120, the first buffer layer 130, the first gate insulating layer GI1, the interlayer insulating layer ILD and the second gate insulating layer GI2.

On this basis, with reference to FIGS. 7A, 10A and 13A, in order to reduce the bending resistance, in the bendable portion 102, for example, only one or two metal layers among the first gate pattern GT1, the second gate pattern GT2, the first source-drain conductive layer SD1 and the second source-drain conductive layer SD2 may be retained as connection leads 180 for signal transmission between the display region and the driver chip and FPC.

Some embodiments of the present disclosure will be schematically described by taking an example in which in the bendable portion 102, only the second source-drain conductive layer SD2 among the first gate pattern GT1, the second gate pattern GT2, the first source-drain conductive layer SD1 and the second source-drain conductive layer SD2 is retained as connection leads 180. However, the implementations of the present disclosure are not limited thereto, and any other metal layers may also be considered as long as the same technical concept is applied.

In this case, as shown in FIGS. 7A, 10A and 13A, the fifth structure 165 may include a barrier layer 120, a first buffer layer 130, a first gate insulating layer GI1, a first interlayer insulating layer ILD1 and a second gate insulating layer GI2 that are stacked, and no inorganic layer exists in the bendable region M3.

In this way, the part of the bendable portion 102 located in the bendable region M3 only includes the first planarization layer PLN1, the second source-drain conductive layer SD2 and the second planarization layer PLN2, which may further reduce the bending resistance of the bendable portion 102, so that the bending radius R of the bendable portion 102 may be smaller. As a result, the bezel of the display apparatus 1000 corresponding to the bendable portion 102 (the lower bezel in FIG. 1) may be made narrower.

As another example, as shown in FIG. 7B, in the case where the pixel circuit 300 includes the low-temperature polysilicon thin film transistors and the oxide transistors, the plurality of inorganic layers may include the barrier layer 120, the first buffer layer 130, the first gate insulating layer GI1, the first interlayer insulating layer ILD1, the second gate insulating layer GI2, the third gate insulating layer GI3 and the second interlayer insulating layer ILD2.

On this basis, in order to reduce the bending resistance, with reference to FIGS. 7B, 10A and 13A, in the bendable portion 102, for example, only one or two metal layers among the first gate pattern GT1, the second gate pattern GT2, the third gate pattern GT3, the first source-drain conductive layer SD1 and the second source-drain conductive layer SD2 may be retained as connection leads 180 for signal transmission between the display region and the driver chip and FPC.

Some embodiments of the present disclosure will be schematically described by taking an example in which in the bendable portion 102, only the second source-drain conductive layer SD2 among the first gate pattern GT1, the second gate pattern GT2, the third gate pattern GT3, the first source-drain conductive layer SD1 and the second source-drain conductive layer SD2 is retained as connection leads 180. However, the implementations of the present disclosure are not limited thereto, and any other metal layers may also be considered as long as the same technical concept is applied.

In this case, as shown in FIGS. 7B, 10A and 13A, the fifth structure 165 may include the barrier layer 120, the first buffer layer 130, the first gate insulating layer GI1, the first interlayer insulating layer ILD1, the second gate insulating layer GI2, the third gate insulating layer GI3 and the second interlayer insulating layer ILD2, and no inorganic layer exists in the bendable region M3.

In this way, the part of the bendable portion 102 located in the bendable region M3 only includes the first planarization layer PLN1, the second source-drain conductive layer SD2 and the second planarization layer PLN2, which may further reduce the bending resistance of the bendable portion 102, so that the bending radius R of the bendable portion 102 may be smaller. As a result, the bezel of the display apparatus 1000 corresponding to the bendable portion 102 (the lower bezel in FIG. 1) may be made narrower.

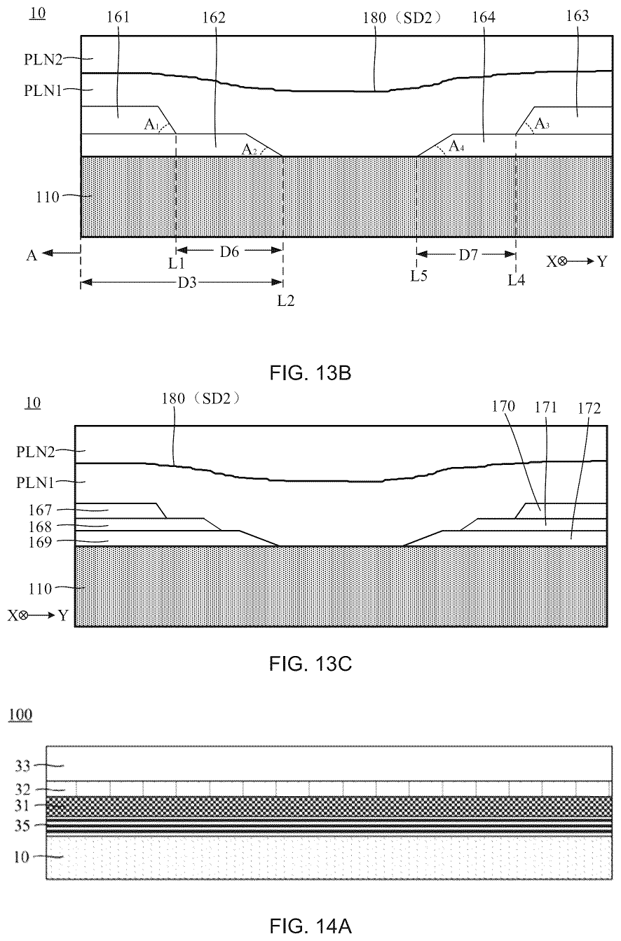

In addition, as shown in FIGS. 10A and 13A, the display panel 10 may further include a sixth structure 166 disposed on the substrate 110. The sixth structure 166 is located in the second transition region M2. The sixth structure 166 and the fifth structure 165 may be made of the same material and formed in the same layer. In this case, during the process of manufacturing the display panel 10, the fifth structure 165 and the sixth structure 166 may be formed by removing all inorganic layers located in the bendable region M3 through one etching process.

In some other examples, as shown in FIG. 10B, the display panel 10 includes a first structure 161 and a second structure 162 disposed on the substrate 110. The first structure 161 and the second structure 162 are located in the first transition region M1, and the first structure 161 is stacked on the second structure 162. The display panel 10 includes a plurality of inorganic layers disposed on the substrate 110, the first structure 161 includes at least one inorganic layer, and the second structure 162 includes at least one inorganic layer.

For example, as shown in FIG. 7A, when the pixel circuit 300 includes only the low-temperature polysilicon thin film transistors, the plurality of inorganic layers may include the barrier layer 120, the first buffer layer 130, the first gate insulating layer GI1, the interlayer insulating layer ILD and the second gate insulating layer GI2.

On this basis, in order to reduce the bending resistance, with reference with FIGS. 7A, 10B and 13B, in the bendable portion 102, for example, only one or two metal layers among the first gate pattern GT1, the second gate pattern GT2, the first source-drain conductive layer SD1 and the second source-drain conductive layer SD2 may be retained as connection leads 180 for signal transmission between the display region and the driver chip and FPC.

Some embodiments of the present disclosure will be schematically described by taking an example in which in the bendable portion 102, only the second source-drain conductive layer SD2 among the first gate pattern GT1, the second gate pattern GT2, the first source-drain conductive layer SD1 and the second source-drain conductive layer SD2 is retained as connection leads 180. However, the implementations of the present disclosure are not limited thereto, and any other metal layers may also be considered as long as the same technical concept is applied.

In this case, as shown in FIGS. 7A, 10B, and 13B, the first structure 161 may include the first gate insulating layer GI1, the first interlayer insulating layer ILD1, and the second gate insulating layer GI2 that are stacked. The second structure 162 may include the barrier layer 120 and the first buffer layer 130 that are stacked. There is no inorganic layer in the bendable region M3.

In this way, the part of the bendable portion 102 located in the bendable region M3 only includes the first planarization layer PLN1, the second source-drain conductive layer SD2 and the second planarization layer PLN2, which may further reduce the bending resistance of the bendable portion 102, so that the bending radius R of the bendable portion 102 may be smaller. As a result, the bezel of the display apparatus 1000 corresponding to the bendable portion 102 (the lower bezel in FIG. 1) may be made narrower.

As another example, as shown in FIG. 7B, in the case where the pixel circuit 300 includes the low-temperature polysilicon thin film transistors and the oxide transistors, the plurality of inorganic layers may include the barrier layer 120, the first buffer layer 130, the first gate insulating layer GI1, the first interlayer insulating layer ILD1, the second gate insulating layer GI2, the third gate insulating layer GI3 and the second interlayer insulating layer ILD2.

On this basis, in order to reduce the bending resistance, with reference to FIGS. 7B, 10B and 13B, in the bendable portion 102, for example, only one or two metal layers among the first gate pattern GT1, the second gate pattern GT2, the third gate pattern GT3, the first source-drain conductive layer SD1 and the second source-drain conductive layer SD2 may be retained as connection leads 180 for signal transmission between the display region and the driver chip and FPC.

Some embodiments of the present disclosure will be schematically described by taking an example in which in the bendable portion 102, only the second source-drain conductive layer SD2 among the first gate pattern GT1, the second gate pattern GT2, the third gate pattern GT3, the first source-drain conductive layer SD1 and the second source-drain conductive layer SD2 is retained as connection leads 180. However, the implementations of the present disclosure are not limited thereto, and any other metal layers may also be considered as long as the same technical concept is applied.

In this case, as shown in FIGS. 7B, 10B, and 13B, the first structure 161 may include the first gate insulating layer GI1, the first interlayer insulating layer ILD1, the second gate insulating layer GI2, the third gate insulating layer GI3, and the second interlayer insulating layer ILD2 that are stacked. The second structure 162 may include the barrier layer 120 and the first buffer layer 130 that are stacked. There is no inorganic layer in the bendable region M3.

In this way, the part of the bendable portion 102 located in the bendable region M3 only includes the first planarization layer PLN1, the second source-drain conductive layer SD2 and the second planarization layer PLN2, which may further reduce the bending resistance of the bendable portion 102, so that the bending radius R of the bendable portion 102 may be smaller. As a result, the bezel of the display apparatus 1000 corresponding to the bendable portion 102 (the lower bezel in FIG. 1) may be made narrower.

In addition, as shown in FIGS. 10B and 13B, the display panel 10 may further include a third structure 163 and a fourth structure 164 disposed on the substrate 110, and the third structure 163 and the fourth structure 164 are located in the second transition region M2. The third structure 163 and the first structure 161 may be made of the same material and formed in the same layer. The fourth structure 164 and the second structure 162 may be made of the same material and formed in the same layer. That is, the third structure 163 is stacked on the fourth structure 164.

In this case, during the process of manufacturing the display panel 10, the first structure 161 and the third structure 163 may be formed by removing some inorganic layers located in the bendable region M3 through one etching process, and the second structure 162 and the fourth structure 164 may be formed by removing some inorganic layers located in the bendable region M3 through one etching process.

Referring to FIGS. 7B and 13B, during the process of forming the first structure 161 and the third structure 163, transfer hole(s) for communicating the first source-drain conductive layer SD1 with the low-temperature polysilicon semiconductor ACT1 may be formed simultaneously. Furthermore, when the pixel circuit 300 includes the oxide transistors, during the process of forming the second structure 162 and the fourth structure 164, transfer hole(s) for communicating the first source-drain conductive layer SD1 with the oxide semiconductor ACT2 may be formed simultaneously.

That is to say, a depth of the transfer hole for communicating the first source-drain conductive layer SD1 with the low-temperature polycrystalline silicon semiconductor ACT1 may be substantially equal to a thickness of the first structure 161; and a depth of the transfer hole for communicating the first source-drain conductive layer SD1 with the oxide semiconductor ACT2 may be substantially equal to a thickness of the second structure 162.

In some other examples, as shown in FIG. 10C, the display panel 10 includes a seventh structure 167, an eighth structure 168, and a ninth structure 169 disposed on the substrate 110; the seventh structure 167, the eighth structure 168, and the ninth structure 169 are located in the first transition region M1; the seventh structure 167 is stacked on the eighth structure 168; and the eighth structure 168 is stacked on the ninth structure 169.

The display panel 10 includes a plurality of inorganic layers disposed on the substrate 110, the seventh structure 167 includes at least one inorganic layer, the eighth structure 168 includes at least one inorganic layer, and the ninth structure 169 includes at least one inorganic layer.

For example, as shown in FIG. 7A, when the pixel circuit 300 includes only the low-temperature polysilicon thin film transistors, the plurality of inorganic layers may include the barrier layer 120, the first buffer layer 130, the first gate insulating layer GI1, the first interlayer insulating layer ILD1, and the second gate insulating layer GI2.

On this basis, in order to reduce the bending resistance, with reference to FIGS. 7A, 10C and 13C, in the bendable portion 102, for example, only one or two metal layers among the first gate pattern GT1, the second gate pattern GT2, the first source-drain conductive layer SD1 and the second source-drain conductive layer SD2 may be retained as connection leads 180 for signal transmission between the display region and the driver chip and FPC.

Some embodiments of the present disclosure will be schematically described by taking an example in which in the bendable portion 102, only the second source-drain conductive layer SD2 among the first gate pattern GT1, the second gate pattern GT2, the first source-drain conductive layer SD1 and the second source-drain conductive layer SD2 is retained as connection leads 180. However, the implementations of the present disclosure are not limited thereto, and any other metal layers may also be considered as long as the same technical concept is applied.

In this case, as shown in FIGS. 7A, 10C, and 13C, the seventh structure 167 may include the first gate insulating layer GI1, the first interlayer insulating layer ILD1, and the second gate insulating layer GI2 that are stacked. The eighth structure 168 may include the first buffer layer 130. The ninth structure 169 may include the barrier layer 120. There is no inorganic layer in the bendable region M3.

In this way, the part of the bendable portion 102 located in the bendable region M3 only includes the first planarization layer PLN1, the second source-drain conductive layer SD2 and the second planarization layer PLN2, which may further reduce the bending resistance of the bendable portion 102, so that the bending radius R of the bendable portion 102 may be smaller. As a result, the bezel of the display apparatus 1000 corresponding to the bendable portion 102 (the lower bezel in FIG. 1) may be made narrower.

As another example, as shown in FIG. 7B, in the case where the pixel circuit 300 includes the low-temperature polysilicon thin film transistors and the oxide transistors, the plurality of inorganic layers may include the barrier layer 120, the first buffer layer 130, the first gate insulating layer GI1, the first interlayer insulating layer ILD1, the second gate insulating layer GI2, the third gate insulating layer GI3 and the second interlayer insulating layer ILD2.

On this basis, in order to reduce the bending resistance, with reference to FIGS. 7B, 10C and 13C, in the bendable portion 102, for example, only one or two metal layers among the first gate pattern GT1, the second gate pattern GT2, the third gate pattern GT3, the first source-drain conductive layer SD1 and the second source-drain conductive layer SD2 may be retained as connection leads 180 for signal transmission between the display region and the driver chip and FPC.

Some embodiments of the present disclosure will be schematically described by taking an example in which in the bendable portion 102, only the second source-drain conductive layer SD2 among the first gate pattern GT1, the second gate pattern GT2, the third gate pattern GT3, the first source-drain conductive layer SD1 and the second source-drain conductive layer SD2 is retained as connection leads 180. However, the implementations of the present disclosure are not limited thereto, and any other metal layers may also be considered as long as the same technical concept is applied.

In this case, as shown in FIGS. 7B, 10C, and 13C, the seventh structure 167 may include the first gate insulating layer GI1, the first interlayer insulating layer ILD1, the second gate insulating layer GI2, the third gate insulating layer GI3, and the second interlayer insulating layer ILD2 that are stacked. The eighth structure 168 may include the first buffer layer 130. The ninth structure 169 may include the barrier layer 120. There is no inorganic layer in the bendable region M3.

In this way, the part of the bendable portion 102 located in the bendable region M3 only includes the first planarization layer PLN1, the second source-drain conductive layer SD2 and the second planarization layer PLN2, which may further reduce the bending resistance of the bendable portion 102, so that the bending radius R of the bendable portion 102 may be smaller. As a result, the bezel of the display apparatus 1000 corresponding to the bendable portion 102 (the lower bezel in FIG. 1) may be made narrower.

In addition, as shown in FIGS. 10C and 13C, the display panel 10 may further include a tenth structure 170, an eleventh structure 171 and a twelfth structure 172 disposed on the substrate 110, and the tenth structure 170, the eleventh structure 171 and the twelfth structure 172 are located in the second transition region M2. The tenth structure 170 and the seventh structure 167 may be made of the same material and formed in the same layer. The eleventh structure 171 and the eighth structure 168 may be made of the same material and formed in the same layer. The twelfth structure 172 and the ninth structure 169 may be made of the same material and formed in the same layer.

In this case, during the process of manufacturing the display panel 10, the seventh structure 167 and the tenth structure 170 may be formed by removing some inorganic layers located in the bendable region M3 through one etching process, the eighth structure 168 and the eleventh structure 171 may be formed by removing some inorganic layers located in the bendable region M3 through one etching process, and the ninth structure 169 and the twelfth structure 172 may be formed by removing some inorganic layers located in the bendable region M3 through one etching process.

Referring to FIGS. 7B and 13C, in the process of forming the seventh structure 167 and the tenth structure 170, transfer hole(s) for communicating the first source-drain conductive layer SD1 with the low-temperature polysilicon semiconductor ACT1 may be formed simultaneously. That is to say, a depth of the transfer hole for communicating the first source-drain conductive layer SD1 with the low-temperature polysilicon semiconductor ACT1 may be substantially equal to a thickness of the seventh structure 167.

Some embodiments of the present disclosure will be schematically described below by taking an example in which the display panel 10 includes the first structure 161, the second structure 162, the third structure 163 and the fourth structure 164. However, the implementations of the present disclosure are not limited thereto, and any other examples may also be considered as long as the same technical concept is applied.

In some embodiments, referring to FIGS. 10A to 12, the display module 100 further includes a back film 71, and the back film 71 is located on the back side of the display panel 10.

Referring to FIGS. 11 and 12, the back film 71 may include, for example, a first back sub-film 711 and a second sub-back sub-film 712, and the first back sub-film 711 and the second back sub-film 712 are disconnected at the bendable portion 102.

In a thickness direction of the display panel 10, the first back sub-film 711 at least partially overlaps the main body 101. The second back sub-film 712 at least partially overlaps the bonding portion 103, and the second back sub-film 712 may be bent along with the bonding portion 103 to the back side 10B of the main body 101 of the display panel 10.

In this case, the back film 71 exposes the bendable portion 102 of the display panel 10, which may reduce the bending resistance of the bendable portion 102 of the display panel 10, change a position of a stress neutral layer in the bendable portion 102 of the display panel 10 during the bending process, and in turn avoid damage to the display panel 10.

In some examples, as shown in FIGS. 11 and 12, an orthographic projection of a boundary of the main body 101 on the reference plane is located within an orthographic projection of a boundary of the first back sub-film 711 on the reference plane. That is, the first back sub-film 711 covers the main body 101. An end of the first back sub-film 711 close to the second back sub-film 712 extends to the bendable portion 102. An orthographic projection of a boundary of the bonding portion 103 on the reference plane is located within an orthographic projection of a boundary of the second back sub-film 712 on the reference plane. That is, the second back sub-film 712 covers the bonding portion 103. An end of the second back sub-film 712 close to the first back sub-film 711 extends to the bendable portion 102.

In this case, during the bending process of the display panel 10, it may be possible to avoid stress concentration at junctions of the main body 101, the bendable portion 102 and the bonding portion 103, reduce the risk of cracks or breakage of the display panel 10 at the junctions of the main body 101, the bendable portion 102 and the bonding portion 103.

In some embodiments, as shown in FIGS. 10B and 13B, an orthographic projection of the first structure 161 on the substrate 110 has a first border L1 away from the display region A. An orthographic projection of the second structure 162 on the substrate 110 has a second border L2 away from the display region A. An orthographic projection of the first back sub-film 711 on the substrate 110 has a third border L3 located in the bendable portion 102.

As shown in FIGS. 10B and 13B, the first border L1, the second border L2, and the third border L3 all extend in the first direction X, and the second border L2 is located between the first border L1 and the third border L3.

That is to say, the second structure 162 is located on an end of the bendable portion 102, and is farther away from the display region A compared with the first structure 161 that is located on the end of the bendable portion 102. The first structure 161 and the second structure 162 form a stepped structure, which is conducive to reducing a slope of the first planarization layer PLN1 between the main body 101 and the bendable portion 102, and reducing a degree of bending of the connection leads 180 in the second source-drain conductive layer SD2 between the bendable portion 102 and the bonding portion 103, and in turn reducing the risk of disconnection of the connection leads 180 and breakage of the bendable portion 102.

Furthermore, as shown in FIG. 10B, the first back sub-film 711 covers a region where the first structure 161 and the second structure 162 are located. For example, the first back sub-film 711 may cover the first transition region M1 and extend to the bendable region M3, so that the part of the bendable portion 102 located in the first transition region M1 extends substantially in a plane, and the risk of cracks or breakage of the display panel 10 at a junction of the first transition region M1 and the bendable region M3 is reduced.

Referring to FIGS. 10B and 13B, a distance D3 between the second border L2 and the lower boundary Z1 of the display region A is less than or equal to 1.2 mm, and is greater than or equal to 0.35 mm.

In some examples, referring to FIGS. 10B and 13B, the distance D3 between the second border L2 and the lower boundary Z1 of the display region A is less than or equal to 1.2 mm, and is greater than or equal to 1.1 mm. For example, the distance D3 between the second border L2 and the lower boundary Z1 of the display region A is any one of 1.2 mm, 1.18 mm, 1.16 mm, 1.15 mm, 1.13 mm, and 1.1 mm.

In this case, the distance between the second border L2 and the lower boundary Z1 of the display region A is larger. That is, a length of the second structure 162 in the second direction Y is larger. A length of the first transition region M1 in the second direction Y is correspondingly larger. The part of the bendable portion 102 located in the first transition region M1 may play a good buffering role, which is conducive to reducing the risk of breakage of the bendable portion 102.

In some other examples, referring to FIGS. 10B and 13B, the distance D3 between the second border L2 and the lower boundary Z1 of the display region A is less than or equal to 1 mm, and is greater than or equal to 0.8 mm. For example, the distance D3 between the second border L2 and the lower boundary Z1 of the display region A is any one of 1 mm, 0.98 mm, 0.95 mm, 0.92 mm, 0.9 mm, 0.88 mm, 0.85 mm, 0.82 mm and 0.8 mm.

In this case, the distance between the second border L2 and the lower boundary Z1 of the display region A is larger. That is, a length of the second structure 162 in the second direction Y is larger. A length of the first transition region M1 in the second direction Y is correspondingly larger. The part of the bendable portion 102 located in the first transition region M1 may play a good buffering role, which is conducive to reducing the risk of breakage of the bendable portion 102. In addition, the bending radius R of the bendable portion 102 may be designed to be small, which facilitates reducing the bezel of the display apparatus 1000 corresponding to the bendable portion 102 (the lower bezel in FIG. 1).

In yet some other examples, referring to FIGS. 10B and 13B, the distance D3 between the second border L2 and the lower boundary Z1 of the display region A is less than or equal to 0.6 mm, and is greater than or equal to 0.55 mm. For example, the distance D3 between the second border L2 and the lower boundary Z1 of the display region A is any one of 0.6 mm, 0.59 mm, 0.58 mm, 0.57 mm, 0.56 mm, and 0.55 mm.

In this case, the distance between the second border L2 and the lower boundary Z1 of the display region A is moderate. That is, the length of the second structure 162 in the second direction Y is moderate. In the case where the part of the bendable portion 102 located in the first transition region M1 has a good buffering effect, the bending radius R of the bendable portion 102 may be designed to be small, so that the bezel of the display apparatus 1000 corresponding to the bendable portion 102 (the lower bezel in FIG. 1) may be made narrower.

In yet some other examples, referring to FIGS. 10B and 13B, the distance D3 between the second border L2 and the lower boundary Z1 of the display region A is less than or equal to 0.5 mm, and is greater than or equal to 0.45 mm. For example, the distance D3 between the second border L2 and the lower boundary Z1 of the display region A is any one of 0.5 mm, 0.49 mm, 0.48 mm, 0.47 mm, 0.46 mm, and 0.45 mm.

In this case, the distance between the second border L2 and the lower boundary Z1 of the display region A is smaller. That is, the length of the second structure 162 in the second direction Y is smaller. The length of the first transition region M1 in the second direction Y is correspondingly smaller. The bending radius R of the bendable portion 102 may be designed to be small, and it is conducive to reducing the length of the bendable portion 102 in the second direction Y. Therefore, the bezel of the display apparatus 1000 corresponding to the bendable portion 102 (the lower bezel in FIG. 1) may be made narrower.

In yet some other examples, referring to FIGS. 10B and 13B, the distance D3 between the second border L2 and the lower boundary Z1 of the display region A is less than or equal to 0.42 mm, and is greater than or equal to 0.35 mm. For example, the distance D3 between the second border L2 and the lower boundary Z1 of the display region A is any one of 0.42 mm, 0.41 mm, 0.4 mm, 0.39 mm, 0.37 mm, and 0.35 mm.

In this case, the distance between the second border L2 and the lower boundary Z1 of the display region A is smaller. That is, the length of the second structure 162 in the second direction Y is smaller. The length of the first transition region M1 in the second direction Y is correspondingly smaller, the bending radius R of the bendable portion 102 may be designed to be small, and the length of the bendable portion 102 in the second direction Y may be further reduced. Therefore, the bezel of the display apparatus 1000 corresponding to the bendable portion 102 (the lower bezel in FIG. 1) may be made narrower.

Referring to FIGS. 10B and 13B, a distance D4 between the second border L2 and the third border L3 is less than or equal to 0.2 mm. For example, the distance D4 between the second border L2 and the third border L3 is less than or equal to 0.12 mm. For example, the distance D4 between the second border L2 and the third border L3 is less than or equal to 0.08 mm. For example, the distance D4 between the second border L2 and the third border L3 is less than or equal to 0.07 mm. For example, the distance D4 between the second border L2 and the third border L3 is less than or equal to 0.06 mm.

For example, the distance D4 between the second border L2 and the third border L3 is any one of 0.2 mm, 0.18 mm, 0.16 mm, 0.15 mm, 1.4 mm, 0.12 mm, 0.11 mm, 0.1 mm, 0.09 mm, 0.08 mm, 0.076 mm, 0.074 mm, 0.072 mm, 0.07 mm, 0.065 mm, 0.06 mm, 0.05 mm, 0.04 mm, 0.03 mm, 0.02 mm and 0.01 mm.

In this case, a length of a portion of the first back sub-film 711 exceeding the second structure 162 in the second direction Y is small, so that the length of the first transition region M1 in the second direction Y is correspondingly small, and the length of the bendable portion 102 in the second direction Y is small. Therefore, the bezel of the display apparatus 1000 corresponding to the bendable portion 102 (the lower bezel in FIG. 1) may be made narrower.

In addition, referring to FIGS. 10B and 13B, an orthographic projection of the third structure 163 on the substrate 110 has a fourth border L4 close to the display region A. An orthographic projection of the fourth structure 164 on the substrate 110 has a fifth border L5 close to the display region A. An orthographic projection of the second back sub-film 712 on the substrate 110 has a sixth border L6 located in the bendable portion 102.

As shown in FIGS. 10B and 13B, the fourth border L4, the fifth border L5, and the sixth border L6 all extend in the first direction X, and the fifth border L5 is located between the fourth border L4 and the sixth border L6.

That is to say, the fourth structure 164 is located on an end of the bendable portion 102, and is farther away from the display region A compared with the third structure 163 that is located at the end of the bendable portion 102. The third structure 163 and the fourth structure 164 form a stepped structure, which is conducive to reducing a slope of the first planarization layer PLN1 between the bendable portion 102 and the bonding portion 103, and reducing the degree of bending of the connection leads 180 in the second source-drain conductive layer SD2 between the bendable portion 102 and the bonding portion 103, and in turn reducing the risk of disconnection of the connection leads 180 and breakage of the bendable portion 102.

Furthermore, the second back sub-film 712 covers a region where the third structure 163 and the fourth structure 164 are located. For example, the second back sub-film 712 may cover the second transition region M2 and extend to the bendable region M3, so that the part of the bendable portion 102 located in the second transition region M2 extends substantially in a plane, and the risk of cracks or breakage of the display panel 10 at a junction of the second transition region M2 and the bendable region M3 is reduced.

Referring to FIG. 10B, a distance D5 between the fifth border L5 and the sixth border L6 is less than or equal to 0.2 mm. For example, the distance D5 between the fifth border L5 and the sixth border L6 is less than or equal to 0.12 mm. For example, the distance D5 between the fifth border L5 and the sixth border L6 is less than or equal to 0.08 mm. For example, the distance D5 between the fifth border L5 and the sixth border L6 is less than or equal to 0.07 mm. For example, the distance D5 between the fifth border L5 and the sixth border L6 is less than or equal to 0.06 mm.

For example, the distance D5 between the fifth border L5 and the sixth border L6 is any one of 0.2 mm, 0.18 mm, 0.16 mm, 0.15 mm, 0.14 mm, 0.12 mm, 0.11 mm, 0.1 mm, 0.09 mm, 0.08 mm, 0.076 mm, 0.074 mm, 0.072 mm, 0.07 mm, 0.065 mm, 0.06 mm, 0.05 mm, 0.04 mm, 0.03 mm, 0.02 mm and 0.01 mm.

In this case, a length of a portion of the second back sub-film 712 exceeding the fourth structure 164 in the second direction Y is small, so that the length of the second transition region M2 in the second direction Y is correspondingly small, and the length of the bendable portion 102 in the second direction Y is small. Therefore, the bezel of the display apparatus 1000 corresponding to the bendable portion 102 (the lower bezel in FIG. 1) may be made narrower.

In some embodiments, as shown in FIG. 13B, a base angle of the first structure 161 away from the display region A is a first angle A₁. The first angle A₁ is in a range of 20° to 70°, that is, 20°≤A₁≤70°.

For example, the first angle A₁ is in a range of 23° to 60°, that is, 23°≤A₁≤60°. For example, the first angle is in a range of 25° to 50°, that is, 25°≤A₁≤50°. For example, the first angle is in a range of 26° to 40°, that is, 26°≤A₁≤40°. For example, the first angle is in a range of 27° to 30°, that is, 27°≤A₁≤30°. For example, the first angle is any one of 23°, 24°, 25°, 26°, 27°, 28°, 29°, 30°, 35°, 40°, 45°, 50°, 55° and 60°.

In this case, it is conducive to reducing the slope of the first planarization layer PLN1 between the main body 101 and the bendable portion 102, reducing the degree of bending of the connection leads 180 in the second source-drain conductive layer SD2 between the bendable portion 102 and the bonding portion 103, and reducing the risk of disconnection of the connection leads 180 and breakage of the bendable portion 102.

It will be noted that a base angle of the third structure 163 close to the display region A is a third angle A₃, and the third angle A₃ may be substantially the same as the first angle A₁, thereby reducing the slope of the first planarization layer PLN1 between the bendable portion 102 and the bonding portion 103, and reducing the risk of disconnection of the connection leads 180 and breakage of the bendable portion 102.

In some embodiments, as shown in FIG. 13B, a base angle of the second structure 162 away from the display region A is a second angle A₂, and the second angle A₂ is in a range of 10° to 30°, that is, 10°≤A₂≤30°.

For example, the second angle A₂ is in a range of 12° to 26° (12°≤A₂≤) 26°. For example, the second angle A₂ is in a range of 14° to 22°, that is, 14°≤A₂≤22°. For example, the second angle A₂ is in a range of 16° to 19°, that is, 16°≤A₂≤19°. For example, the second angle A₂ is in a range of 16° to 28°, that is, 16°≤A₂≤18°. For example, the second angle A₂ is any one of 10°, 11°, 12°, 14°, 16°, 17°, 18°, 19°, 20°, 22°, 25°, 26°, 28° and 30°.

In this case, it is conducive to reducing the slope of the first planarization layer PLN1 between the main body 101 and the bendable portion 102, reducing the degree of bending of the connection leads 180 in the second source-drain conductive layer SD2 between the bendable portion 102 and the bonding portion 103, and reducing the risk of disconnection of the connection leads 180 and breakage of the bendable portion 102.

In addition, as shown in FIG. 13B, a base angle of the fourth structure 164 close to the display region A is a fourth angle A₄, and the fourth angle A₄ may be substantially the same as the second angle A₂, thereby reducing the slope of the first planarization layer PLN1 between the bendable portion 102 and the bonding portion 103, and reducing the risk of disconnection of the connection leads 180 and breakage of the bendable portion 102.

On this basis, the base angle of the second structure 162 away from the display region A is the second angle A₂, and the distance between the first border L1 and the second border L2 is a sixth distance D6. The sixth distance D6 and the second angle A₂ satisfy the following formula:

$$0.08 \leq {( sin {A}_{2} )}^{2} \times \sqrt[2]{D 6} \leq 0.3 .$$

Furthermore, the sixth distance D6 and the second angle A₂ satisfy the following formula:

$$0.09 \leq {( sin {A}_{2} )}^{2} \times \sqrt[2]{D 6} \leq 0.28 .$$

Furthermore, the sixth distance D6 and the second angle A₂ satisfy the following formula:

$$0.1 \leq {( sin {A}_{2} )}^{2} \times \sqrt[2]{D 6} \leq 0.25$$

In this case, it is conducive to reducing the slope of the first planarization layer PLN1 between the main body 101 and the bendable portion 102, reducing the degree of bending of the connection leads 180 in the second source-drain conductive layer SD2 between the bendable portion 102 and the bonding portion 103, and reducing the risk of disconnection of the connection leads 180 and breakage of the bendable portion 102. Moreover, it is conducive to reducing the bending radius R of the bendable portion 102.

In addition, as shown in FIG. 13B, the base angle of the fourth structure 164 close to the display region A is the fourth angle A₄, and the distance between the fourth border L4 and the fifth border L5 is a seventh distance D7. The seventh distance D7 and the fourth angle A₄ satisfy the following formula:

$$0.08 \leq {( sin {A}_{4} )}^{2} \times \sqrt[2]{D 7} \leq 0.3 .$$

Furthermore, the seventh distance D7 and the fourth angle A₄ satisfy the following formula:

$$0.09 \leq {( sin {A}_{4} )}^{2} \times \sqrt[2]{D 7} \leq 0.28 .$$

Furthermore, the seventh distance D7 and the fourth angle A₄ satisfy the following formula:

$$0.1 \leq {( sin {A}_{4} )}^{2} \times \sqrt[2]{D 7} \leq 0.25 .$$

In this case, it is conducive to reducing the slope of the first planarization layer PLN1 between the bendable portion 102 and the bonding portion 103, reducing the degree of bending of the connection leads 180 in the second source-drain conductive layer SD2 between the bendable portion 102 and the bonding portion 103, and reducing the risk of disconnection of the connection leads 180 and breakage of the bendable portion 102. Moreover, it is conducive to reducing the bending radius R of the bendable portion 102.

In some embodiments, referring to FIGS. 11, 12, and 14A to 14C, the display module 100 further includes an anti-reflection layer 31, a second adhesive layer 32 and a cover plate 33.

As shown in FIGS. 5 and 11, the boundary Z of the display region A of the main body 101 is located within a boundary of an orthographic projection of the anti-reflection layer 31 on the reference plane, so as to improve the ability of the entire display region A to resist interference from external ambient light. For example, the anti-reflection layer 31 may completely cover a region where the main body 101 is located, and extend to a region where the bendable portion 102 is located.

It will be noted that a boundary line between the main body 101 and the bendable portion 102 may be shown in FIG. 10B, which is substantially flush with a lower border (a border close to the bendable portion 102) of the anti-reflection layer 31. Alternatively, the boundary line between the main body 101 and the bendable portion 102 may be shown in FIG. 11, which is not flush with the lower border (the border close to the bendable portion 102) of the anti-reflection layer 31. The embodiments of the present disclosure are not specifically limited thereto.

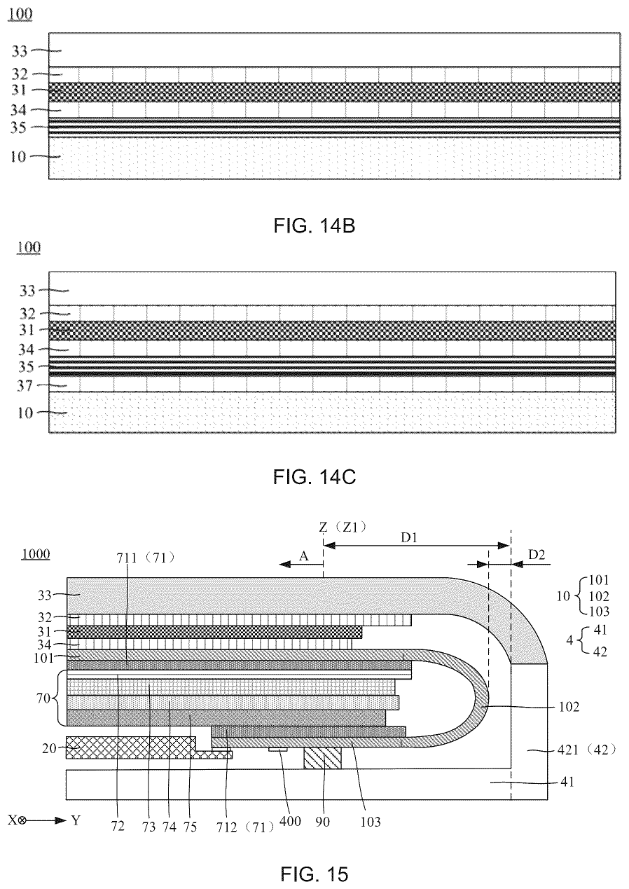

In some examples, as shown in FIGS. 7A and 14A, the anti-reflection layer 31 may be directly disposed on a side of the encapsulation layer 12 of the display panel 10 away from the display substrate 11. That is, the anti-reflection layer 31 may be directly formed on the side of the encapsulation layer 12 of the display panel 10 away from the display substrate 11 through a semiconductor process.

In some other examples, as shown in FIGS. 7B and 14B, the display module 100 further includes a first adhesive layer 34, and the first adhesive layer 34 is disposed between the anti-reflection layer 31 and the main body 101 of the display panel 10, so as to bond the anti-reflection layer 31 to the main body 101 of the display panel 10. That is, the anti-reflection layer 31 may be indirectly formed on the side of the encapsulation layer 12 of the display panel 10 away from the display substrate 11 through an adhesive bonding process.

It will be noted that a material of the first adhesive layer 34 includes a transparent glue layer. Here, the transparent glue layer refers to a glue layer whose transmittance is greater than or equal to 90%. For example, the material of the first adhesive layer 34 may include optical adhesive, which is not specifically limited in the embodiments of the present disclosure.

A boundary of an orthographic projection of the first adhesive layer 34 on the reference plane is located within a boundary of an orthographic projection of the main body 101 on the reference plane. For example, the boundary of the orthographic projection of the first adhesive layer 34 on the reference plane substantially coincides with the boundary Z of the display region A of the main body 101.

As shown in FIG. 14A, the second adhesive layer 32 is disposed on a side of the anti-reflection layer 31 away from the main body 101, so as to bond the anti-reflection layer 31 to the cover plate 33.

It will be noted that a material of the second adhesive layer 32 includes a transparent glue layer. Here, the transparent glue layer refers to a glue layer whose transmittance is greater than or equal to 90%. For example, the material of the second adhesive layer 32 may include optical adhesive, which is not specifically limited in the embodiments of the present disclosure.

The second adhesive layer 32 may extend beyond the reflective layer 31, so that the second adhesive layer 32 exists in a region between the anti-reflective layer 31 and the cover plate 33, which makes the anti-reflective layer 31 and the cover plate 33 more firmly bonded. For example, an orthographic projection of the second adhesive layer 32 on the reference plane may at least partially overlap with an orthographic projection of the bendable portion 102 on the reference plane.

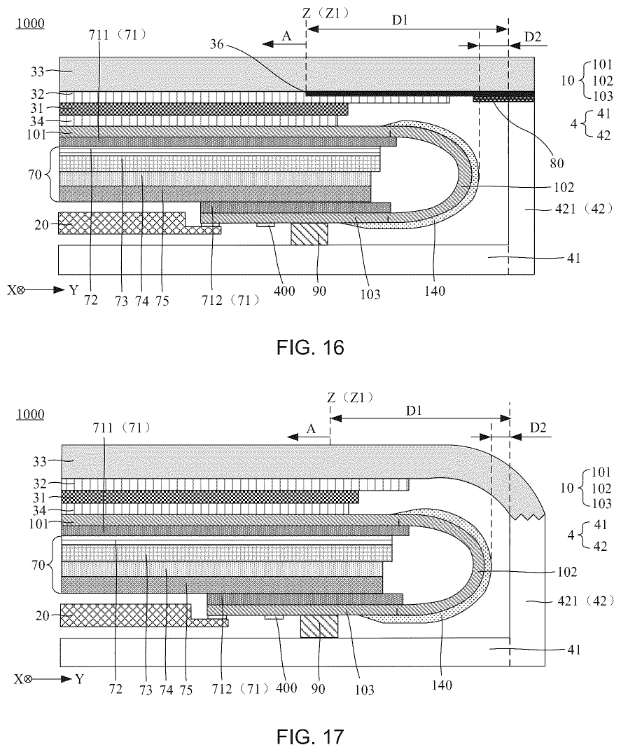

As shown in FIG. 14A, the cover plate 33 is disposed on a side of the second adhesive layer 32 away from the main body 101 to protect the display panel 10. The cover plate 33 may be a flat cover plate as shown in FIG. 16, or a curved cover plate as shown in FIG. 15, which will not be specifically limited in the embodiments of the present disclosure.

It will be noted that a boundary of an orthographic projection of the display panel 10 on the reference plane is located within a boundary of an orthographic projection of the cover plate 33 on the reference plane.

The cover plate 33 may be of a single-layer structure or a multi-layer structure.

In some examples, referring to FIG. 12, the cover plate 33 is a single-layer glass cover plate. A thickness of the glass cover plate may be, for example, greater than or equal to 1 mm. For example, the thickness of the glass cover plate is any one of 1 mm, 1.2 mm, 1.5 mm, 2 mm, 2.5 mm, 3 mm, and 5 mm.

In some other examples, the cover plate 33 includes inorganic cover plate(s) and/or organic cover plate(s) in a direction perpendicular to the cover plate 33 and pointing from the substrate 110 to the encapsulation layer 12. There may be one or more inorganic cover plates. There may be one or more organic cover plates.

For example, the cover plate 33 includes a plurality of inorganic cover plates that are sequentially stacked. For example, the cover plate 33 includes a plurality of organic cover plates that are sequentially stacked. For example, the cover plate 33 includes one inorganic cover plate and one organic cover plate that are sequentially stacked.

It will be noted that the plurality of inorganic cover plates may be bonded to each other through a transparent adhesive, or the plurality of organic cover plates may be bonded to each other through a transparent adhesive, or the inorganic cover plate and the organic cover plate may be bonded to each other through a transparent adhesive, which will not be specifically limited in the embodiments of the present disclosure. The light transmittance of the transparent adhesive is greater than or equal to 90%.

A thickness of the inorganic cover plate is in a range of 10 μm to 200 μm. For example, the thickness of the inorganic cover plate 331 may be in a range of 20 μm to 100 μm. For example, the thickness of the inorganic cover plate 331 may be in a range of 25 μm to 50 μm. For example, the thickness of the inorganic cover plate 331 may be any one of 10 μm, 20 μm, 25 μm, 30 μm, 50 μm, 100 μm, 150 μm, and 200 μm.

A thickness of the organic cover plate may be in a range from 5 μm to 300 μm. For example, the thickness of the organic cover plate 332 may be in a range of 20 μm to 100 μm. For example, the thickness of the organic cover plate 332 may be in a range of 25 μm to 50 μm. For example, the thickness of the organic cover plate 332 may be any one of 5 μm, 10 μm, 15 μm, 20 μm, 25 μm, 30 μm, 50 μm, 100 μm, 150 μm, 200 μm, 250 μm, and 300 μm.

A material of the inorganic cover plate 331 may include, for example, flexible thin glass, and a thickness of the flexible thin glass is less than or equal to 100 μm. A material of the organic cover plate 332 may include, for example, at least one of polyimide, polycarbonate, polyamide, triacetyl cellulose, polymethyl methacrylate, and polyethylene terephthalate.

In some embodiments, referring to FIGS. 14A to 14C, the display module 100 further includes a touch layer 35.

Referring to FIGS. 7B and 14A, the touch layer 35 may be directly formed on the side of the encapsulation layer 12 of the display panel 10 away from the display substrate 11 through a semiconductor process. The touch layer 35 may also be indirectly formed on the side of the encapsulation layer 12 of the display panel 10 away from the display substrate 11 through an adhesive bonding process.

In some examples, as shown in FIGS. 14A and 14B, the touch layer 35 is directly disposed on the side of the encapsulation layer 12 of the display panel 10 away from the display substrate 11, that is, the touch layer 35 is directly formed on the side of the encapsulation layer 12 of the display panel 10 away from the display substrate 11 through a semiconductor process, that is, no other film layer is provided between the touch layer 35 and the encapsulation layer 12. In this way, the display apparatus 1000 (see FIG. 1) has a small thickness, which facilitates realizing thinness and lightness. For example, compared with a case of attaching the touch layer 35 to the display panel 10, the thickness of the display apparatus 1000 may be reduced by about one tenth or more.

In some other examples, as shown in FIG. 14C, a fourth adhesive layer 37 is provided between the touch layer 35 and the encapsulation layer 12 to bond the touch layer 35 to the display panel 10.

It will be noted that a material of the fourth adhesive layer 37 includes a transparent glue layer. Here, the transparent glue layer refers to a glue layer whose transmittance is greater than or equal to 90%. For example, the material of the fourth adhesive layer 37 may include optical adhesive, which is not specifically limited in the embodiments of the present disclosure.

It will be noted that, in the case where the display module 100 includes the anti-reflection layer 31, the touch layer 35 may be, for example, located between the display panel 10 and the anti-reflection layer 31.

In addition, the touch layer 35 has a touch region, and the touch region covers the display region A. Thus, the user may perform touch operations in the entire display region A for control and selection.

Referring FIGS. 12 to 14C, the touch layer 35 includes a plurality of driving electrodes and a plurality of sensing electrodes that are insulated from each other. A capacitive node may be formed between a driving electrode and a sensing electrode. A pulse or alternating voltage applied to the driving electrodes by a touch chip may induce charges on the sensing electrodes, and an amount of the induced charges is susceptible to external factors (e.g., touch or proximity of a finger). That is to say, when a finger touches or approaches the capacitive node, capacitance change may occur at the capacitive node; and the touch chip may measure the capacitance change through the sensing electrodes, and determine a location of the touch or proximity of the finger based on the measurement of the capacitance change in the entire touch layer 35.

It will be noted that the driving electrodes and the sensing electrodes may be arranged in the same layer or in different layers, which will not be specifically limited in the embodiments of the present disclosure.

In some embodiments, referring to FIGS. 16 and 18 to 31, the display module 100 further includes a light-shielding layer 36 to shield regions (e.g., the peripheral region B and the region where the bendable portion 102 is located) outside the display region A (see FIG. 5) of the display panel 10, thus preventing light leakage.

For example, as shown in FIGS. 5 and 16, orthographic projections of the peripheral region B and the bendable portion 102 of the display panel 10 on the reference plane may be located within an orthographic projection of the light-shielding layer 36 on the reference plane. That is, an inner boundary of the orthographic projection of the light-shielding layer 36 on the reference plane may, for example, coincide with the boundary Z of the display region A. Furthermore, outer boundaries of the orthographic projections of the peripheral region B and the bendable portion 102 of the display panel 10 on the reference plane may be located within an outer boundary of the orthographic projection of the light-shielding layer 36 on the reference plane. An outer boundary of the light-shielding layer 36 may, for example, coincide with a boundary of the cover plate 33.

It will be noted that the light-shielding layer 36 may be formed on a surface of the cover plate 33 close to the display panel 10 through a screen printing process. The adhesion between the light-shielding layer 36 and the cover plate 33 is strong, which make it less likely to detach.

In some embodiments, as shown in FIGS. 2 and 15 to 31, the display apparatus 1000 may further include a housing 40. The display panel 10 may be arranged inside the housing 40.

For example, referring to FIG. 2, a longitudinal section of the housing 40 is U-shaped. For example, the housing 40 includes a bottom plate 41 and a frame 42 surrounding the bottom plate 41. The bottom plate 41 is disposed on the back side of the display panel 10, and the frame 42 surrounds a periphery of the display panel 10.

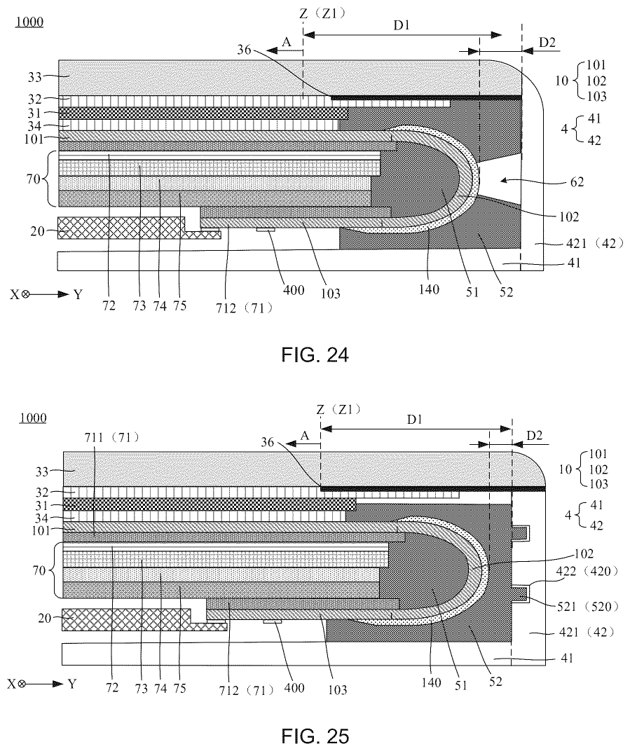

In some examples, as shown in FIGS. 21 and 24, a boundary of an orthographic projection of the cover plate 33 on the reference plane substantially coincides with an inner boundary of an orthographic projection of the frame 42 on the reference plane, and the cover plate 33 is connected to an inner side surface of the frame 42. In this way, the frame 42 may protect edges of the cover plate 33 and reduce the risk of the edges of the cover plate 33 being broken due to accidental collision.

In some other examples, as shown in FIGS. 15 to 19, 23, 25 to 27, 29 and 31, the orthographic projection of the frame 42 on the reference plane is located within the orthographic projection of the cover plate 33 on the reference plane, and the cover plate 33 is connected to an end face of the frame 42 away from the bottom plate 41. In this way, the frame 42 may support the cover plate 33, and the cover plate 33 may completely cover the frame 42. There is no frame 42 on the display side. Thus, it facilitates a curved transition design of the edges of the display apparatus 1000, and the cost is low.

As shown in FIGS. 15 and 16, two end faces of the cover plate 33 and the frame 42 that are connected may be planar surfaces. As shown in FIG. 17, the end face of the cover plate 33 connected to the frame 42 may have an uneven pattern, and the end face of the frame 42 connected to the cover plate 33 may also have an uneven pattern. The end face of the cover plate 33 with an uneven pattern and the end face of the frame 42 with an uneven pattern match each other and are engaged. As a result, the firmness of the connection between the cover plate 33 and the frame 42 is improved.

In yet some other examples, as shown in FIG. 29, the orthographic projection of the frame 42 on the reference plane is located within the orthographic projection of the cover plate 33 on the reference plane, and there is a gap between the cover plate 33 and the frame 42.

On this basis, referring to FIGS. 16, 23 and 29, the display apparatus 1000 may further include a sealing component 80. An end of the sealing component 80 is connected to the cover plate 33, and another end of the sealing component 80 is connected to the frame 42, so as to prevent a shortened service life of the display panel 10 caused by water vapor and oxygen in the external environment entering the housing 40 and then corroding the display panel 10. A material of the sealing component 80 may include, for example, resin.

Referring to FIGS. 16, 23 and 29, an orthographic projection of the sealing component 80 on the reference plane at least partially coincides with the orthographic projection of the frame 42 on the reference plane.

For example, as shown in FIG. 29, the orthographic projection of the frame 42 on the reference plane substantially coincides with the orthographic projection of the sealing component 80 on the reference plane.

For example, as shown in FIG. 16, an outer boundary of the orthographic projection of the frame 42 on the reference plane substantially coincides with an outer boundary of the orthographic projection of the sealing component 80 on the reference plane. An inner boundary of the orthographic projection of the sealing component 80 on the reference plane is located within the inner boundary of the orthographic projection of the frame 42 on the reference plane. That is to say, the orthographic projection of the frame 42 on the reference plane is located within the orthographic projection of the sealing component 80 on the reference plane. There is a gap between the sealing component 80 and the second adhesive layer 32.

For example, as shown in FIG. 23, the outer boundary of the orthographic projection of the frame 42 on the reference plane substantially coincides with the outer boundary of the orthographic projection of the sealing component 80 on the reference plane, and the inner boundary of the orthographic projection of the sealing component 80 on the reference plane is located within the inner boundary of the orthographic projection of the frame 42 on the reference plane. The sealing component 80 is in contact with the second adhesive layer 32.

It will be noted that the term “contact” should be understood in a broad sense, and may represent to a fixed connection, a detachable connection, or abutment or attachment. In addition, “contact” may represent a direct contact (i.e., there is no other component (or region, layer, portion) between two components (or regions, layers, portions)), or may represent an indirect contact through an intermediate medium (i.e., there is other component (or region, layer, portion) between two components (or regions, layers, portions)).

That is to say, the orthographic projection of the frame 42 on the reference plane is located within the orthographic projection of the sealing component 80 on the reference plane. In addition, the sealing component 80 may, for example, extend toward an inner side of the frame 42 to an end of the second adhesive layer 32 close to the frame 42, and is in contact with the second adhesive layer 32.

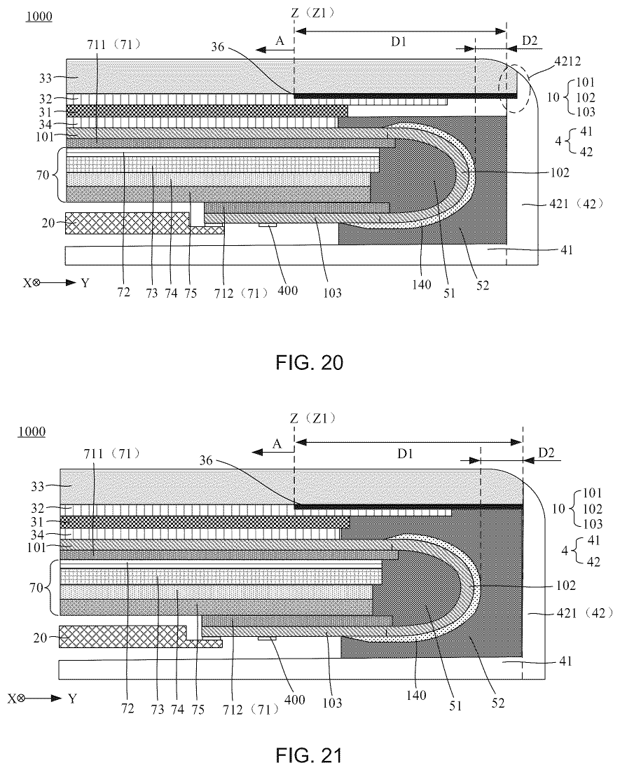

In yet some other examples, as shown in FIG. 20, an end of the frame 42 away from the bottom plate 41 is provided with a step 4212. The boundary of the orthographic projection of the cover plate 33 on the reference plane substantially coincides with an outer boundary of an orthographic projection of the step 4212 on the reference plane, and the cover plate 33 is connected to the step 4212. In this way, the frame 42 may support the cover plate 33 and protect edges of the cover plate 33, thereby reducing the risk of the edges of the cover plate 33 being broken due to accidental collision. In addition, the cover plate 33 and the frame 42 have a good connection and fixing effect.

Referring to FIG. 15, a part of the frame 42 located on a side of the bendable portion 102 of the display panel 10 away from the main body 101 is a first frame 421. A minimum distance between the lower boundary Z1 of the display region A and a boundary of an orthographic projection of the first frame 421 on the reference plane is a first distance D1. A minimum distance between a boundary of an orthographic projection of the bendable portion 102 on the reference plane and the boundary of the orthographic projection of the first frame 421 on the reference plane is a second distance D2.

It will be noted that the reference plane is a plane where a surface of the display region A of the display side 10A of the main body 101 of the display panel 10 is located.

On this basis, a ratio of the first distance D1 to the second distance D2 is greater than or equal to 5 and less than or equal to 10. Furthermore, the ratio of the first distance D1 to the second distance D2 is greater than or equal to 5.5 and less than or equal to 7. Furthermore, the ratio of the first distance D1 to the second distance D2 is greater than or equal to 5.7 and less than or equal to 6. In this way, it is possible to avoid interference of the bendable portion 102 of the display panel 10 with the assembly of the frame 42, and avoid the risk of cracks or breakage of the bendable portion 102 caused by the frame 42 colliding with the bendable portion 102 of the display panel 10. In addition, the bezel of the display apparatus 1000 may be reduced to increase the screen-to-body ratio.

In some embodiments, referring to FIG. 15, the first distance D1 is less than or equal to 1.9 mm. For example, the first distance D1 is in a range of 1 mm to 1.9 mm. For example, the first distance D1 is in a range of 1 mm to 1.7 mm. For example, the first distance D1 is in a range of 1.5 mm to 1.6 mm. For example, the first distance D1 is any one of 1 mm, 1.2 mm, 1.3 mm, 1.5 mm, 1.6 mm, 1.7 mm, and 1.9 mm.

In some embodiments, referring to FIG. 15, the second distance D2 is less than or equal to 0.3 mm. For example, the second distance D2 is in a range of 0.1 mm to 0.3 mm. For example, the second distance D2 is in a range of 0.2 mm to 0.3 mm. For example, the second distance D2 is any one of 0.1 mm, 0.15 mm, 0.2 mm, 0.25 mm, and 0.3 mm.

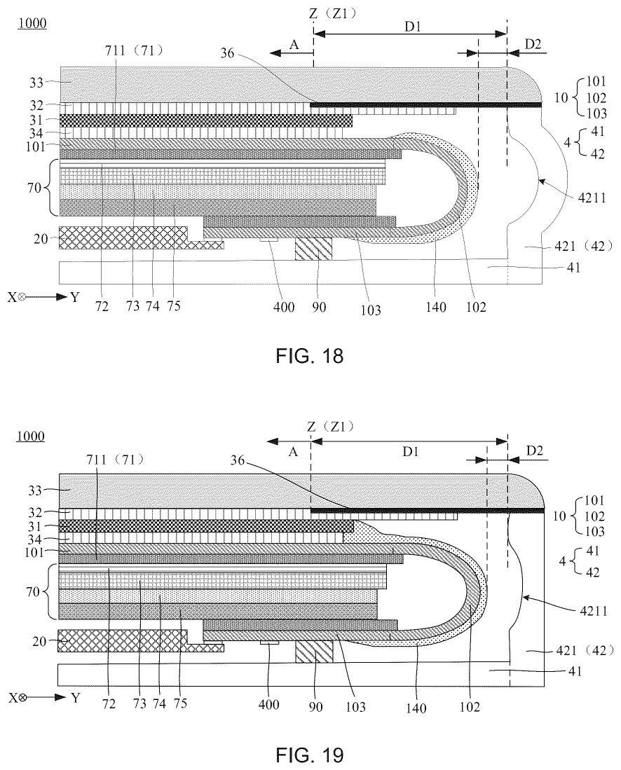

In some embodiments, referring to FIGS. 18 and 19, the inner side of the first frame 421 is recessed in a direction away from the bendable portion 102, so as to form an avoidance structure 4211.

As shown in FIGS. 18 and 19, in the second direction Y (which is substantially parallel to the reference plane and points from the main body 101 to the bendable portion 102), the avoidance structure 4211 is at least opposite to a part of the bendable portion 102 that is farthest from the main body 101. Moreover, a minimum distance between the bendable portion 102 and the avoidance structure 4211 is greater than or equal to a first preset value. In this case, since the inner side of the first frame 421 is bent in the direction away from the bendable portion 102, it may be possible to reduce the second distance D2, and reduce the first distance D1, and in turn reduce the bezel of the display apparatus 1000 and improving the screen-to-body ratio of the display apparatus 1000.

Here, the first preset value is a process limit value at which the bendable portion 102 does not interfere with the first frame 421. For example, the first preset value is greater than or equal to 0.1 mm. For example, the first preset value is in a range of 0.1 mm to 0.3 mm. For example, the first preset value is any one of 0.1 mm, 0.15 mm, 0.2 mm, 0.25 mm and 0.3 mm.

It will be noted that the second direction Y is substantially parallel to the reference plane, and substantially perpendicular to an extending direction of a length of the first frame 421.

In some examples, as shown in FIG. 18, the avoidance structure 4211 is completely opposite to the bendable portion 102, and a cross section of the avoidance structure 4211 matches a cross section of the bendable portion 102. For example, the cross section of the avoidance structure 4211 and the cross section of the bendable portion 102 are both substantially in a shape of a semicircle. In this way, it may be possible to further reduce the second distance D2, and reduce the first distance D1, and in turn reduce the bezel of the display apparatus 1000 and improving the screen-to-body ratio of the display apparatus 1000.

It will be noted that, herein, the cross section is substantially perpendicular to the reference plane and substantially parallel to the second direction Y.

It will be understood that when the inner side of the first frame 421 is recessed in the direction away from the bendable portion 102 to form the avoidance structure 4211, an outer side surface of the first frame 421 may be a planar surface, or may be in other shapes matching the avoidance structure 4211.

In some examples, as shown in FIG. 18, the inner side of the first frame 421 is recessed in the direction away from the bendable portion 102 to form the avoidance structure 4211, and an outer side of the first frame 421 is also recessed in the direction away from the bendable portion 102, so that a thickness of the first frame 421 is uniform.

In some other examples, as shown in FIG. 19, the inner side of the first frame 421 is recessed in the direction away from the bendable portion 102 to form the avoidance structure 4211, and the outer side of the first frame 421 is of a planar structure.

In some embodiments, referring to FIGS. 16 to 31, the display module 100 may further include a first protective layer 140 located on the display side of the display panel 10, and the first protective layer 140 covers a surface of the bendable portion 102 close to the first frame 421.

For example, the orthographic projection of the first back sub-film 711 on the substrate 110 partially overlaps with an orthographic projection of the first protective layer 140 on the substrate 110. An orthographic projection of the second back sub-film 712 on the substrate 110 partially overlaps with the orthographic projection of the first protective layer 140 on the substrate.

For example, an end of the first protective layer 140 extends to the main body 101, and another end of the first protective layer 140 extends to the bonding portion 103. That is, a portion of the first protective layer 140 covering the bendable portion 102 overlaps portions of the first back sub-film 711 and the second back sub-film 712 covering the bendable portion 102; a portion of the first protective layer 140 extending to the main body 101 overlaps a portion of the first back sub-film 711 covering the main body 101; and a portion of the first protective layer 140 extending to the bonding portion 103 overlaps a portion of the second back sub-film 712 covering the bonding portion 103.

In this way, the first protective layer 140 may change the position of the stress neutral layer in the bendable portion 102 of the display panel 10 during the bending process, thus reducing the risk of cracks or breakage of the display panel 10 at the junctions of the main body 101, the bendable portion 102 and the bonding portion 103.

It will be noted that, when the display module 100 includes the first protective layer 140, the second distance D2 is a minimum distance between a boundary of the orthographic projection of the first protective layer 140 on the reference plane and the boundary of the orthographic projection of the first frame 421 on the reference plane.

As shown in FIG. 10B, when the display panel 10 includes the second structure 162, the first protective layer 140 further covers at least a part of the second structure 162. For example, an end of the first protective layer 140 extends to the main body 101, and another end of the first protective layer 140 extends to the bonding portion 103. That is, the first protective layer 140 completely covers the second structure 162.

As shown in FIG. 10B, when the display panel 10 includes the fourth structure 164, the first protective layer 140 further covers at least a part of the fourth structure 164. For example, an end of the first protective layer 140 extends to the main body 101, and another end of the first protective layer 140 extends to the bonding portion 103. That is, the first protective layer 140 completely covers the fourth structure 164.

The embodiments of the present disclosure will be illustrated below by taking an example in which the display module 100 includes the first protective layer 140, and the second distance D2 is a minimum distance between a boundary of the orthographic projection of the first protective layer 140 on the reference plane and the boundary of the orthographic projection of the first frame 421 on the reference plane. However, the implementations of the present disclosure are not limited thereto.

In some examples, referring to FIG. 19, when the display module 100 includes the anti-reflection layer 31, the first protective layer 140 further covers an end of the anti-reflection layer 31 close to the first frame 421. That is, the first protective layer 140 is in contact with the anti-reflection layer 31 to improve the sealing performance and reduce the risk of shortened service life of the display panel 10 caused by water vapor and oxygen in the external environment entering the display panel 10.

In some other examples, referring to FIG. 19, when the display module 100 includes the anti-reflection layer 31, a gap exists between the first protective layer 140 and the anti-reflection layer 31, which facilitates the fabrication of the first protective layer 140 and reduces the process difficulty.

In some examples, referring to FIG. 7A, the anti-reflection layer 31 includes a polarizer, and the polarizer is disposed on the side of the encapsulation layer 12 away from the display substrate 11. The polarizer transmits light of a certain polarization direction, thereby reducing the reflection intensity of the external ambient light on the display panel 10.

In some other examples, the anti-reflection layer 31 includes a black matrix and a color filter. The black matrix is used to separate light emitted from different sub-pixels P, and reduce reflected light after the external ambient light enters the display panel 10. The color film may filter out most wavelength bands of ambient light, thereby reducing the reflection intensity of the ambient light on the display panel 10.

On this basis, as shown in FIG. 19, when the display module 100 further includes the first adhesive layer 34, the first protective layer 140 further covers an end of the first adhesive layer 34 close to the first frame 421. That is, the first protective layer 140 further covers ends of the first adhesive layer 34 and the anti-reflection layer 31 close to the first frame 421, so as to improve the sealing performance and reduce the risk of shortened service life of the display panel 10 caused by water vapor and oxygen in the external environment entering the display panel 10.

In some embodiments, referring to FIG. 20, the display apparatus 1000 further includes a first fixed portion 51 and a second fixed portion 52.

As shown in FIG. 20, the first fixed portion 51 covers a side of the bendable portion 102 away from the first frame 421, and extends to the main body 101 and the bonding portion 103, thus protecting the bendable portion 102.

For example, the first fixed portion 51 fills the side of the bendable portion 102 away from the first frame 421, which may have a fixing, stress dispersing and buffering function for the bendable portion 102, thereby reducing the risk of cracks or breakage of the bendable portion 102.

As shown in FIG. 20, the second fixed portion 52 covers at least a part of a side of the bendable portion 102 close to the first frame 421, and extends to the main body 101 and the bonding portion 103, thus protecting the bendable portion 102. For example, the second fixed portion 52 fills a space between the bendable portion 102 and the first frame 421, which may have a fixing, protecting and buffering function for the bendable portion 102, thereby reducing the risk of cracks or breakage of the bendable portion 102.

It will be noted that, the second fixed portion 52 fills the space between the bendable portion 102 and the first frame 421, and the second fixed portion 52 may further fill a space between rest of the frame and the display panel 10 to play a buffering and fixing role, which is not specifically limited in the embodiments of the present disclosure.

In addition, the first fixed portion 51 is connected to the second fixed portion 52, and the first fixed portion 51 and the second fixed portion 52 may be integrally formed in the same process step. For example, the first fixed portion 51 and the second fixed portion 52 may be formed by an injection molding process or a 3D printing process. The first fixed portion 51 and the second fixed portion 52 are formed by the injection molding process or 3D printing process before the housing 40 is assembled, so as to avoid the housing 40 directly colliding with the bendable portion 102 during the assembly of the housing 40. Of course, the first fixed portion 51 and the second fixed portion 52 may be formed by the injection molding process after the housing 40 is assembled, which is not specifically limited in the embodiments of the present disclosure. It will be noted that a fixed structure (the first fixed portion 51 and the second fixed portion 52) formed by the 3D printing process may be referred to as a printed fixed structure or a printed component.

Referring to FIGS. 18, 20, 21 and 22, the second fixed portion 52 may be in contact with the cover plate 33 and/or the second adhesive layer 32, or may not be in contact with the cover plate 33 and the second adhesive layer 32 (that is, gaps exist between the second fixed portion 52 and the cover plate 33 and the second adhesive layer 32). Furthermore, the second fixed portion 52 may be in contact with the bottom plate 41, or may not be in contact with the bottom plate 41 (that is, there is a gap between the second fixed portion 52 and the bottom plate 41).

For example, as shown in FIG. 20, the second fixed portion 52 is not in contact with the cover plate 33 and the second adhesive layer 32, that is, there is a gap between a side of the second fixed portion 52 and each of the cover plate 33 and the second adhesive layer 32, and another side of the second fixed portion 52 is in contact with the bottom plate 41 of the housing 40. In this way, the bottom plate 41 may support and fix the second fixed portion 52.

For example, as shown in FIG. 21, a side of the second fixed portion 52 is in contact with each of the cover plate 33 and the second adhesive layer 32, and another side of the second fixed portion 52 is connected to the bottom plate 41 of the housing 40. In this way, the bottom plate 41 may support and fix the second fixed portion 52, and the second fixed portion 52 may also support the cover plate 33.

For example, as shown in FIG. 21, the boundary of the orthographic projection of the cover plate 33 on the reference plane substantially coincides with the inner boundary of the orthographic projection of the frame 42 on the reference plane, and the cover plate 33 is connected to the inner side surface of the frame 42.

In this case, the frame 42 cannot directly support the cover plate 33, and the frame 42 may indirectly provide great support for the cover plate 33 through the second fixed portion 52, so as to reduce the pressure on the display panel 10 and increase the service life of the display panel 10.

As another example, as shown in FIG. 23, the orthographic projection of the frame 42 on the reference plane is located within the orthographic projection of the cover plate 33 on the reference plane, and there is a gap between the cover plate 33 and the frame 42. An end of the sealing component 80 is connected to the cover plate 33, and another end of the sealing component 80 is connected to the frame 42.

In this case, the frame 42 cannot directly support the cover plate 33, and the frame 42 may indirectly provide great support for the cover plate 33 through the sealing component 80 and the second fixed portion 52, so as to reduce the pressure on the display panel 10 and increase the service life of the display panel 10.

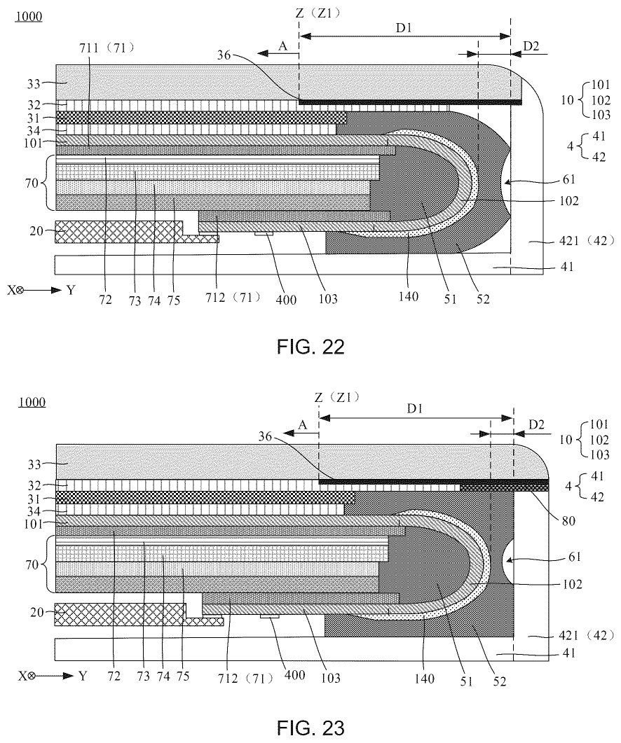

For example, as shown in FIG. 22, a side of the second fixed portion 52 is in contact with the second adhesive layer 32, and another side of the second fixed portion 52 is connected to the bottom plate 41 of the housing 40. In this way, the bottom plate 41 may support and fix the second fixed portion 52, and the second fixed portion 52 may also support the cover plate 33.

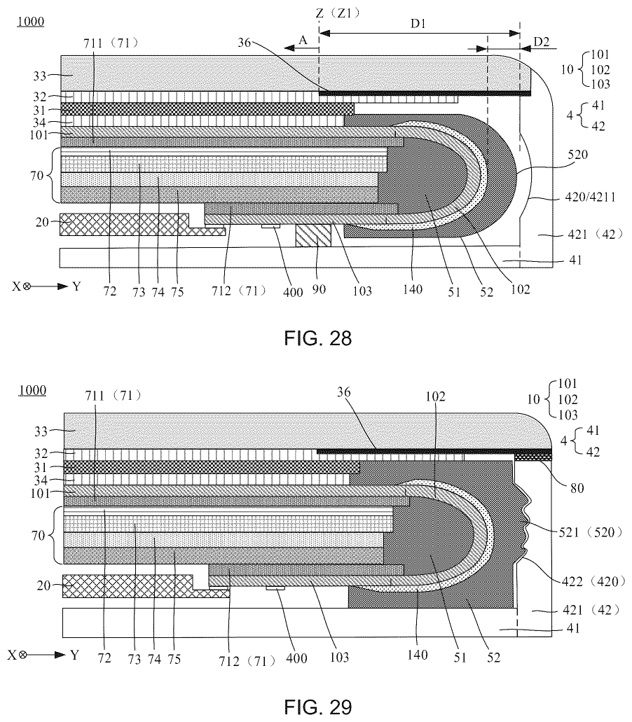

For example, referring to FIG. 28, the second fixed portion 52 is not in contact with the cover plate 33 and the second adhesive layer 32, that is, there is a gap between a side of the second fixed portion 52 and each of the cover plate 33 and the second adhesive layer 32, and there is a gap between another side of the second fixed portion 52 and the bottom plate 41 of the housing 40.

In this case, the display apparatus 1000 may further include a support pad 90, and the support pad 90 is disposed between the bottom plate 41 and the display panel 10 to provide support.

It will be noted that, when the display apparatus 1000 does not include the second fixed portion 52, as shown in FIG. 15, the display apparatus 1000 may also include a support pad 90, and the support pad 90 is disposed between the bottom plate 41 and the display panel 10 to provide support.

In some examples, as shown in FIGS. 22 and 23, the second fixed portion 52 covers the side of the bendable portion 102 close to the first frame 421, and the second fixed portion 52 and the first frame 421 enclose at least one first cavity 61.

For example, as shown in FIG. 23, the second fixed portion 52 covers the side of the bendable portion 102 close to the first frame 421, and the second fixed portion 52 and the first frame 421 enclose one first cavity 61. The first cavity 61 may be, for example, located between a part with a highest degree of bending of the bendable portion 102 and the first frame 421.

It will be understood that the bending stress on the part with the highest degree of bending of the bendable portion 102 is great, resulting in a high risk of cracks or breakage. In light of this, when the first frame 421 is subjected to pressure, due to the first cavity 61, the pressure will not be directly transmitted to the part with the highest degree of bending of the bendable portion 102 through the second fixed portion 52. The pressure is dispersed by the second fixed portion 52 and then transmitted to other parts of the bendable portion 102. Therefore, the risk of cracks or breakage in the part with the highest degree of bending of the bendable portion 102 is reduced.

It will be noted that a shape of a cross section of the first cavity 61 may be substantially any one of regular shapes such as a bow, a triangle, a trapezoid and a rectangle. Alternatively, the shape of the cross section of the first cavity 61 may be an irregular shape, which is not specifically limited in the embodiments of the present disclosure.

In some other examples, as shown in FIG. 24, the second fixed portion 52 covers the part of the side of the bendable portion 102 close to the first frame 421, and the second fixed portion 52, the bendable portion 102 and the first frame 421 enclose at least one second cavity 62.

For example, as shown in FIG. 24, the second fixed portion 52 covers the part of the side of the bendable portion 102 close to the first frame 421, and the second fixed portion 52, the bendable portion 102 and the first frame 421 enclose one second cavity 62. The second cavity 62 may, for example, expose the part with a highest degree of bending of the bendable portion 102.

It will be understood that the bending stress on the part with the highest degree of bending of the bendable portion 102 is great, resulting in a high risk of cracks or breakage. In light of this, when the first frame 421 is subjected to pressure, due to the second cavity 62, the pressure will not be transmitted to the part with the highest degree of bending of the bendable portion 102 through the second fixed portion 52. Therefore, the risk of cracks or breakage of the bendable portion 102 is reduced.

It will be noted that a shape of a cross section of the second cavity 62 may be substantially any one of regular shapes such as a bow, a triangle, a trapezoid and a rectangle. Alternatively, the shape of the cross section of the second cavity 62 may be an irregular shape, which is not specifically limited in the embodiments of the present disclosure.

In some embodiments, referring to FIGS. 25 to 31, the second fixed portion 52 is provided with a first limiting structure 520, and the first frame 421 is provided with a second limiting structure 420.

The first limiting structure 520 is located on a side of the second fixed portion 52 close to the first frame 421, the second limiting structure 420 is located on a side of the first frame 421 close to the second fixed portion 52, and the first limiting structure 520 is connected to the second limiting structure 420, so as to limit the relative motion of the second fixed portion 52 with respect to the first frame 421.

In some examples, as shown in FIG. 28, the side of the second fixed portion 52 close to the first frame 421 is in a shape of an arc, so as to form the first limiting structure 520. The side of the first frame 421 close to the second fixed portion 52 is depressed inward, so as to form the second limiting structure 420. The first limiting structure 520 is located inside the second limiting structure 420. A shape of a cross section of the first limiting structure 520 and a shape of a cross section of the second limiting structure 420 are bow-shaped and match each other.

It will be noted that the second limiting structure 420 may also be used as the above-mentioned avoidance structure 4211, which is not specifically limited in the embodiments of the present disclosure here.

In some examples, referring to FIGS. 25, 26, 29 and 30, the first limiting structure 520 includes at least one first limiting protrusion 521, and the second limiting structure 420 includes at least one first limiting groove 422, and the first limiting protrusion 521 is located in the first limiting groove 422.

It will be noted that a shape of a cross section of the first limiting groove 422 and a shape of a cross section of the first limiting protrusion 521 may each be substantially any one of regular shapes such as a bow, a semicircle, a semi-ellipse, a rectangle, and a triangle. Alternatively, the shape of the cross section of the first limiting groove 422 and the shape of the cross section of the first limiting protrusion 521 may be irregular shapes, as long as the shape of the cross section of the first limiting groove 422 matches the shape of the cross section of the first limiting protrusion 521.

For example, as shown in FIG. 29, the first limiting structure 520 includes one first limiting protrusion 521, and the second limiting structure 420 includes one first limiting groove 422. The first limiting protrusion 521 matches the first limiting groove 422, and the first limiting protrusion 521 is located in the first limiting groove 422. Shapes of cross sections of the first limiting groove 422 and the first limiting protrusion 521 are sawtooth shapes and match each other.

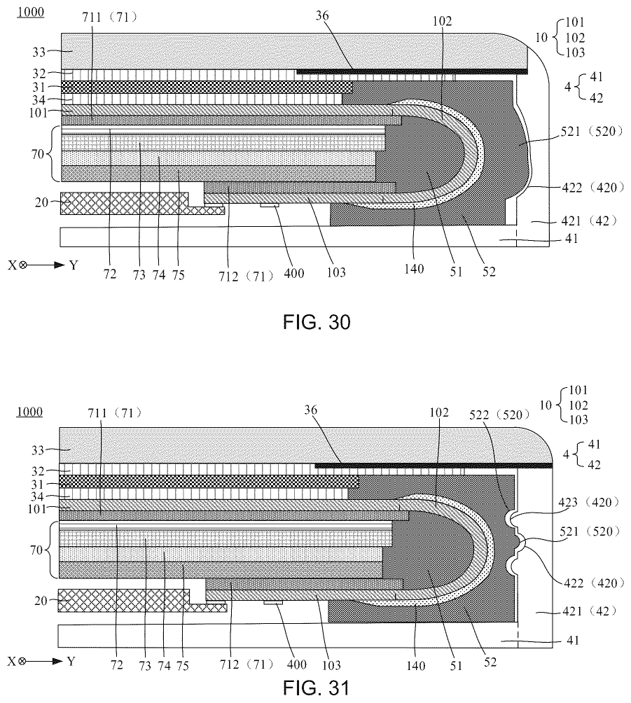

For another example, as shown in FIG. 30, the first limiting structure 520 includes one first limiting protrusion 521, and the second limiting structure 420 includes one first limiting groove 422. The first limiting protrusion 521 matches the first limiting groove 422, and the first limiting protrusion 521 is located in the first limiting groove 422. Shapes of cross sections of the first limiting groove 422 and the first limiting protrusion 521 are irregular shapes with arc segments and match each other.

For yet another example, as shown in FIG. 25, the first limiting structure 520 includes two first limiting protrusions 521, and the second limiting structure 420 includes two first limiting grooves 422; one first limiting protrusion 521 matches one first limiting groove 422, and one first limiting protrusion 521 is located in one first limiting groove 422. Shapes of cross sections of the first limiting groove 422 and the first limiting protrusion 521 are rectangular and match each other.

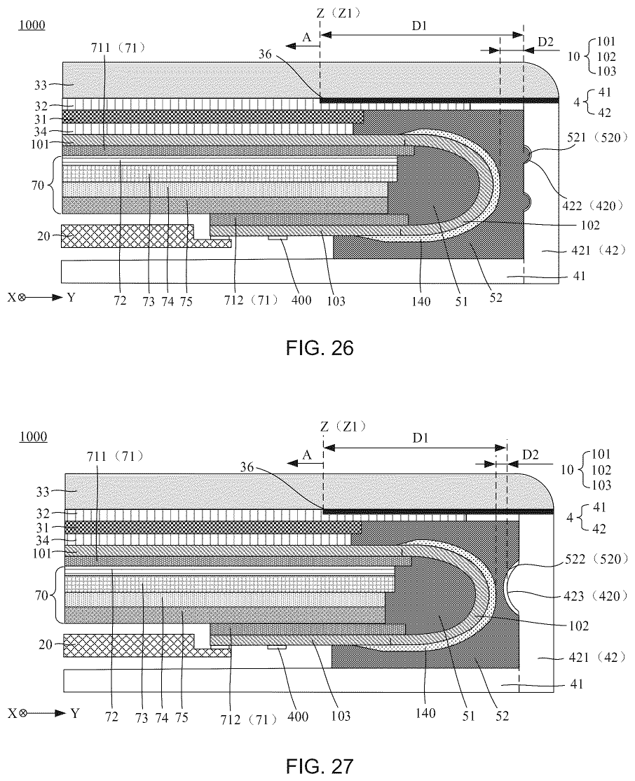

For yet another example, as shown in FIG. 26, the first limiting structure 520 includes two first limiting protrusions 521, and the second limiting structure 420 includes two first limiting grooves 422; one first limiting protrusion 521 matches one first limiting groove 422, and one first limiting protrusion 521 is located in one first limiting groove 422. Shapes of cross sections of the first limiting groove 422 and the first limiting protrusion 521 are bow-shaped and match each other.

In some other examples, referring to FIG. 27, the first limiting structure 520 includes at least one second limiting groove 522, and the second limiting structure 420 includes at least one second limiting protrusion 423. The second limiting protrusion 423 is located in the second limiting groove 522.

For example, as shown in FIG. 27, the first limiting structure 520 includes one second limiting groove 522, and the second limiting structure 420 includes one second limiting protrusion 423. The second limiting protrusion 423 matches the second limiting groove 522, and the second limiting protrusion 423 is located in the second limiting groove 522. FIG. 27 illustrates an example in which shapes of cross sections of the second limiting groove 522 and the second limiting protrusion 423 are bow-shaped.

In yet some other examples, referring to FIG. 31, the first limiting structure 520 includes at least one first limiting protrusion 521 and at least one second limiting groove 522, the second limiting structure 420 includes at least one first limiting groove 422 and at least one second limiting protrusion 423, the first limiting protrusion 521 is located in the first limiting groove 422, and the second limiting protrusion 423 is located in the second limiting groove 522.

For example, as shown in FIG. 31, the first limiting structure 520 includes one first limiting protrusion 521 and two second limiting grooves 522, and the second limiting structure 420 includes one first limiting groove 422 and two second limiting protrusions 423. One first limiting protrusion 521 matches one first limiting groove 422, and one first limiting protrusion 521 is located in one first limiting groove 422. One second limiting protrusion 423 matches one second limiting groove 522, and one second limiting protrusion 423 is located in one second limiting groove 522. FIG. 31 illustrates an example in which shapes of cross sections of the first limiting groove 422, the second limiting groove 522, the first limiting protrusion 521, and the second limiting protrusion 423 are bow-shaped.

In some embodiments, as shown in FIGS. 11 and 12, the display apparatus 1000 further includes a heat dissipation assembly 70, and the heat dissipation assembly 70 is disposed on the back side 10B of the main body 101 of the display panel 10.

In some examples, referring to FIGS. 11 and 12, the heat dissipation assembly 70 may include a third adhesive layer 72, a second buffer layer 73, a second protective layer 74 and a heat dissipation layer 75 that are stacked in sequence.

It will be noted that, for example, bonding adhesive layers may be provided between the second buffer layer 73, the second protective layer 74 and the heat dissipation layer 75, which will not be specifically limited in the embodiments of the present disclosure. In addition, in some other examples, there may be no second protective layer 74 in the heat dissipation assembly 70, and the embodiments of the present disclosure are not specifically limited thereto.

Referring to FIG. 12, an orthogonal projection of the third adhesive layer 72 on the reference plane may be, for example, in a shape of a grid, The grid-like structure of the third adhesive layer 72 may prevent bubbles from being generated during an adhesive bonding process of the third adhesive layer 72 and the back film 71, thereby avoiding defects such as bulges in the back film 71.

It will be noted that a material of the third adhesive layer 72 includes a glue layer. For example, the material of the third adhesive layer 72 includes an optical adhesive and/or pressure-sensitive adhesive, which is not specifically limited in the embodiments of the present disclosure.

Referring to FIG. 12, in the thickness direction of the display panel 10, the third adhesive layer 72 and the first back sub-film 711 at least partially overlap. For example, as shown in FIG. 12, an orthographic projection of a boundary of the third adhesive layer 72 on the reference plane is located within the orthographic projection of the boundary of the first back sub-film 711 on the reference plane.

Referring to FIG. 12, the second buffer layer 73 mainly plays a role of buffering and shock resistance, so as to improve the impact resistance of the display apparatus 1000.

Referring to FIG. 12, an orthographic projection of a boundary of the second buffer layer 73 on the reference plane may be, for example, located within the orthographic projection of the boundary of the main body 101 on the reference plane.

In addition, the second buffer layer 73 may be of a single-layer structure or a multi-layer stacked structure. The second buffer layer 73 may include at least one layer of a polyimide (PI) layer, a polyethylene terephthalate (PET) plastic layer, or a foam layer.

For example, the second buffer layer 73 may be composed of PET plastic and graphite. For example, a support frame is formed by using PET plastic, and graphite is filled in the support frame. In this way, the second buffer layer 73 may also have a heat dissipation function.

Referring to FIG. 12, the second protective layer 74 mainly play a role of stress releasing. The second protective layer 74 may have a certain deformation after being subjected to stress (tensile stress or compressive stress), and the rebound force inside the second protective layer 74 may be released by the deformation of the second protective layer 74. Therefore, the possibility of film separation in the display panel 10 is reduced.

Referring to FIG. 12, an orthographic projection of a boundary of the second protective layer 74 on the reference plane is located within the orthographic projection of the boundary of the main body 101 on the reference plane.

For example, as shown in FIG. 12, the orthographic projection of the boundary of the second protective layer 74 on the reference plane is located between the orthographic projection of the boundary of the main body 101 on the reference plane and the orthographic projection of the boundary of the second buffer layer 73 on the reference plane.

Referring to FIG. 12, the heat dissipation layer 75 may be of a single-layer structure or a multi-layer stacked structure. The heat dissipation layer 75 may include metal. For example, the heat dissipation layer 75 includes at least one of copper, silver, or steel. Alternatively, the heat dissipation layer 75 may include non-metal. For example, the heat dissipation layer 75 includes graphite.

Referring to FIG. 12, an orthographic projection of a boundary of the heat dissipation layer 75 on the reference plane is located within the orthographic projection of the boundary of the main body 101 on the reference plane.

For example, as shown in FIG. 12, the orthographic projection of the boundary of the heat dissipation layer 75 on the reference plane is located within the orthographic projection of the boundary of the second protective layer 74 on the reference plane.

In addition, the heat dissipation layer 75 may be electrically connected to the housing 40. The heat dissipation layer 75 may transmit heat or charges to the housing 40, thereby realizing grounding of the heat dissipation layer 75 and facilitating the heat dissipation of the heat dissipation layer 75.

It will be understood that, referring to FIG. 12, the circuit board 20 is located on a side of the heat dissipation assembly 70 away from the main body 101 of the display panel 10, and is connected to the bonding portion 103. That is, the bonding portion 103 is located on the side of the heat dissipation assembly 70 away from the main body 101 of the display panel 10.

In this case, referring to FIGS. 12, 15 to 19, and 28, when the display apparatus 1000 includes the support pad 90, the support pad 90 may be, for example, disposed on a side of the bonding portion 103 away from the main body 101 of the display panel 10. An end of the support pad 90 is connected to the bottom plate 41, and another end of the support pad 90 is connected to the bonding portion 103, so as to support the display panel 10 and the heat dissipation assembly 70.

The foregoing descriptions are merely specific implementation manners of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display module, comprising:
a display panel having a display side and a back side opposite to each other, wherein the display panel includes a main body, a bonding potion, and a bendable portion located between the main body and the bonding potion; the main body has a display region; the bendable portion is capable of being bent toward the back side of the main body along a bending axis extending in a first direction, so that the bonding potion is bent to the back side of the main body; the bendable portion includes a first transition region, a second transition region, and a bendable region located between the first transition region and the second transition region, and the first transition region is adjacent to the main body;
the display panel includes a substrate and a plurality of inorganic layers disposed on the substrate; the display panel further includes a first structure and a second structure located in the first transition region, and the first structure is stacked on the second structure; the first structure includes at least one inorganic layer, and the second structure includes at least one inorganic layer;
a back film located on the back side of the display panel, wherein the back film includes a first back sub-film and a second back sub-film, the first back sub-film covers the main body, the second back sub-film covers the bonding portion, and the first back sub-film and the second back sub-film are disconnected at the bendable portion; and
a first protective layer located on the display side of the display panel, wherein the first protective layer covers the bendable portion and at least a part of the second structure; and an orthographic projection of the first back sub-film on the substrate partially overlaps with an orthographic projection of the first protective layer on the substrate.

2. The display module according to claim 1, wherein an orthographic projection of the first structure on the substrate has a first border away from the display region; an orthographic projection of the second structure on the substrate has a second border away from the display region; the orthographic projection of the first back sub-film on the substrate has a third border located in the bendable portion;
the first border, the second border, and the third border all extend in a first direction, and the second border is located between the first border and the third border.

3. The display module according to claim 2, wherein a distance between the second border and a lower boundary of the display region is less than or equal to 0.42 mm, and is greater than or equal to 0.35 mm.

4. The display module according to claim 2, wherein a distance between the second border and a lower boundary of the display region is less than or equal to 0.5 mm, and is greater than or equal to 0.45 mm.

5. The display module according to claim 2, wherein a distance between the second border and a lower boundary of the display region is less than or equal to 0.6 mm, and is greater than or equal to 0.55 mm.

6. The display module according to claim 2, wherein a distance between the second border and the third border is less than or equal to 0.2 mm.

7. The display module according to claim 6, wherein the distance between the second border and the third border is less than or equal to 0.08 mm.

8. The display module according to claim 1, wherein a base angle of the first structure away from the display region is a first angle, and the first angle is in a range of 20° to 70°; and/or a base angle of the second structure away from the display region is a second angle, and the second angle is in a range of 10° to 30°.

9. The display module according to claim 8, wherein the first angle is in a range of 23° to 60°; and/or the second angle is in a range of 12° to 26°.

10. The display module according to claim 9, wherein the first angle is in a range of 25° to 50°; and/or the second angle is in a range of 14° to 22°.

11. The display module according to claim 2, wherein a base angle of the second structure away from the display region is a second angle A₂, and a distance between the first border and the second border is a distance D6, where 0.08≤(sinA₂)²×\sqrt{D6}≤0.3.

12. The display module according to claim 11, wherein the base angle of the second structure away from the display region is the second angle A₂, and the distance between the first border and the second border is the distance D6, where 0.09≤(sinA₂)²×\sqrt{D6}≤0.28.

13. The display module according to claim 1, wherein the plurality of inorganic layers include a barrier layer, a first buffer layer, a first gate insulating layer, a first interlayer insulating layer, a second gate insulating layer, a third gate insulating layer, and a second interlayer insulating layer;
the first structure includes the first gate insulating layer, the first interlayer insulating layer, the second gate insulating layer, the third gate insulating layer and the second interlayer insulating layer that are stacked in sequence; and the second structure includes the barrier layer and the first buffer layer that are stacked.

14. The display module according to claim 1, further comprising: an anti-reflection layer, a second adhesive layer, and a cover plate, wherein the anti-reflection layer is disposed on the display side of the main body of the display panel; the second adhesive layer is disposed on a side of the anti-reflection layer away from the main body; the cover plate is disposed on a side of the second adhesive layer away from the main body; and the first protective layer is in contact with the anti-reflection layer.

15. A display apparatus, comprising:
the display module according to claim 1; and
a housing including a bottom plate and a frame surrounding the bottom plate, wherein the bottom plate is disposed on the back side of the display panel of the display module, and the frame surrounds a periphery of the display panel.

16. The display apparatus according to claim 15, wherein a part of the frame located on a side of the bendable portion of the display panel away from the main body of the display panel is a first frame;
a minimum distance between a boundary of the display region and a boundary of an orthographic projection of the first frame on a reference plane is a first distance, the reference plane being a plane where a display surface of the main body of the display panel is located; a minimum distance between a boundary of an orthographic projection of the bendable portion on the reference plane and the boundary of the orthographic projection of the first frame on the reference plane is a second distance; and a ratio of the first distance to the second distance is greater than or equal to 5 and less than or equal to 10.

17. The display apparatus according to claim 15, wherein a part of the frame located on a side of the bendable portion of the display panel away from the main body is a first frame; an inner side of the first frame is recessed in a direction away from the bendable portion to form an avoidance structure;
in a second direction, the avoidance structure is at least opposite to a part of the bendable portion that is farthest from the main body, the second direction is substantially parallel to a reference plane and points from the main body to the bendable portion, and the reference plane is a plane where a display surface of the main body of the display panel is located; a minimum distance between the bendable portion and the avoidance structure is greater than or equal to a first preset value, and the first preset value is a process limit value at which the bendable portion does not interfere with the first frame.

18. The display apparatus according to claim 16, wherein a part of the frame located on a side of the bendable portion of the display panel away from the main body is a first frame; the display apparatus further comprises:
a first fixed portion covering a side of the bendable portion away from the first frame and extending to the main body and the bonding portion;
a second fixed portion covering at least a part of a side of the bendable portion close to the first frame and extending to the main body and the bonding portion.

19. The display apparatus according to claim 18, wherein the second fixed portion covers the side of the bendable portion close to the first frame, and the second fixed portion and the first frame enclose at least one first cavity; and/or the second fixed portion covers the part of the side of the bendable portion close to the first frame, and the second fixed portion, the bendable portion and the first frame enclose at least one second cavity.

20. The display apparatus according to claim 18, wherein the second fixed portion is provided with a first limiting structure, and the first limiting structure is located on a side of the second fixed portion close to the first frame; the first frame is provided with a second limiting structure, and the second limiting structure is located on a side of the first frame close to the second fixed portion;
the first limiting structure is connected to the second limiting structure to limit a relative motion of the second fixed portion with respect to the first frame.
